(19) United States
(12) Patent Application Publication
(10) Pub. No.: US 2026/0123161 A1
(43) Pub. Date: Apr. 30, 2026

(54) DISPLAY DEVICE AND METHOD FOR MANUFACTURING THE SAME AND ELECTRONIC DEVICE

(71) Applicant: Samsung Display Co., Ltd., Yongin-si (KR)

(72) Inventors: Jung An LEE, Yongin-si (KR); Gwang Geun LEE, Yongin-si (KR); Young Kyo SEO, Yongin-si (KR); So Yeon YOON, Yongin-si (KR)

(21) Appl. No.: 19/295,477

(22) Filed: Aug. 8, 2025

(30) Foreign Application Priority Data
Oct. 30, 2024 (KR) 10-2024-0150547

(51) Int. Cl. H10H 29/856; H01L 25/075; H10H 29/01; H10H 29/49; H10H 29/851

(52) U.S. Cl. CPC H10H 29/856; H10H 29/012; H10H 29/0361; H10H 29/0363; H10H 29/49; H10H 29/8512; H10W 90/00

(57) ABSTRACT

A display device, a method for manufacturing the same, and an electronic device are provided. The display device includes a substrate, a pixel electrode layer on the substrate, a light emitting element on the pixel electrode layer and including a contact electrode, an organic layer in an island pattern shape covering a portion of a side surface of the light emitting element and a portion of the pixel electrode layer exposed by the light emitting element, a first reflective layer arranged on a side surface of the organic layer, and a protective layer protecting the light emitting element, the organic layer, and the first reflective layer.

### CROSS-REFERENCE TO RELATED APPLICATION

The present application claims priority to and the benefit of Korean Patent Application No. 10-2024-0150547, filed on Oct. 30, 2024, in the Korean Intellectual Property Office, the entire disclosure of which is incorporated herein by reference.

### BACKGROUND

### 1. Field

One or more embodiments of the present disclosure relate to a display device, a method for manufacturing the same, and an electronic device.

### 2. Description of the Related Art

As the information society develops, demands for display devices that display various information in the form of images are rapidly increasing in various suitable forms. For instance, the display devices may be flat panel display devices such as liquid crystal displays, field emission displays, and/or light emitting displays.

The light emitting displays may include, for example, an organic light emitting display including an organic light emitting diode element as a light emitting element and/or a micro-light emitting display including a micro-light emitting diode element (hereinafter, referred to as a micro-light emitting element) as a light emitting element.

Because micro-light emitting diode elements are made of inorganic materials, they have less deterioration issues and thus a longer life than organic light emitting diode elements.

### SUMMARY

Aspects and features of embodiments of the present disclosure are directed toward a display device and a manufacturing method thereof that may increase light extraction efficiency and reduce power consumption.

However, aspects of the present disclosure are not restricted to those set forth herein. The above and other aspects of the present disclosure will become more apparent to one of ordinary skill in the art to which the present disclosure pertains by referencing the detailed description of the present disclosure given hereinafter.

According to one or more embodiments of the present disclosure, a display device includes a substrate, a pixel electrode layer on (e.g., arranged on) the substrate, a light emitting element on (e.g., arranged on) the pixel electrode layer and including a contact electrode, an organic layer in an island pattern shape covering a portion of a side surface of the light emitting element and a portion of the pixel electrode layer exposed by the light emitting element, a first reflective layer on (e.g., arranged on) a side surface of the organic layer, and a protective layer protecting the light emitting element, the organic layer, and the first reflective layer.

According to one or more embodiments, the protective layer includes: a first protective layer covering a top surface and side surfaces of the light emitting element and the pixel electrode layer on which the light emitting element is not arranged; a second protective layer on (e.g., arranged on) a top surface of the organic layer and the top surface and side surfaces of the light emitting element; and a third protective layer on (e.g., arranged on) the second protective layer, and on the light emitting element, the organic layer, and the substrate on which the organic layer is not arranged.

According to one or more embodiments, the second protective layer has a tip protruding outward from the top surface of the organic layer, wherein the first reflective layer is arranged below the tip.

According to one or more embodiments, the organic layer has a cross-section of one selected from among a dome shape, a rectangle shape, and a trapezoid shape. For example, the organic layer has a cross-section of a dome shape, a rectangle shape, or a trapezoid shape.

According to one or more embodiments, the organic layer has a shape that gradually narrows as it goes upward in a thickness direction of the display device.

According to one or more embodiments, the side surface of the organic layer and the first reflective layer each have an inclination angle in a range of about 55° to about 85°.

According to one or more embodiments, the light emitting element further includes: a conductive layer on (e.g., arranged) on a bottom surface of a first semiconductor layer; the first semiconductor layer on (e.g., arranged on) the conductive layer and including a semiconductor material layer doped with a first conductive dopant; an active layer on (e.g., arranged on) the first semiconductor layer; and a second semiconductor layer on (e.g., arranged on) the active layer and including a semiconductor material layer doped with a second conductive dopant, wherein the organic layer surrounds a side surface of the conductive layer, the first semiconductor layer, and the active layer.

According to one or more embodiments, the light emitting element further includes a third semiconductor layer, which is an undoped semiconductor layer, on (e.g., arranged on) the second semiconductor layer.

According to one or more embodiments, the light emitting element further includes a light extraction pattern having a concave pattern on an upper portion of the light emitting element.

According to one or more embodiments, the contact electrode includes a first contact electrode on (e.g., arranged on) a protective film and connected to the conductive layer exposed without being covered by the protective film, and a second contact electrode on (e.g., arranged on) the protective film and in (e.g., arranged in) a hole penetrating the conductive layer and a portion of a semiconductor stack, which includes the first semiconductor layer, the active layer, and the second semiconductor layer, wherein the pixel electrode layer includes a pixel electrode and a common electrode that are spaced and/or apart (e.g., spaced apart or separated) from each other, wherein the first contact electrode is connected to the pixel electrode, and the second contact electrode is connected to the common electrode.

According to one or more embodiments, the pixel electrode layer includes a pixel electrode, wherein the contact electrode is on (e.g., arranged on) the pixel electrode and connected to the conductive layer that is exposed and not covered by a protective film.

According to one or more embodiments, the display device further includes a common electrode on (e.g., arranged on) the light emitting element and the organic layer, wherein the protective layer includes an opening that exposes at least a portion of an upper portion of the light emitting element, and the upper portion of the light emitting element is connected to the common electrode through the opening.

According to one or more embodiments, the display device further includes: a partition wall arranged to be around (e.g., surround) the light emitting element; and a reflective layer on (e.g., arranged on) a side surface of the partition wall and a bottom of a space formed by the partition wall.

According to one or more embodiments, the display device further includes a wavelength conversion layer in (e.g., arranged on) a space formed by the partition wall.

According to one or more embodiments, the display device further includes a capping layer, an overcoat layer, and a color filter layer sequentially arranged on the wavelength conversion layer and the partition wall.

According to one or more embodiments of the present disclosure, a method for manufacturing a display device includes: forming a light emitting element including a plurality of semiconductor layers, a conductive layer, a protective layer, and a contact electrode; transferring the light emitting element onto a circuit board; forming a first protective layer by applying a first layer to a side of the light emitting element and the circuit board on which the light emitting element is not arranged; forming an organic material layer covering the side of the light emitting element, forming a protective material layer to cover the light emitting element and the organic material layer, and patterning the protective material layer and the organic material layer to form an organic layer and a second protective layer; completely depositing a reflective material layer to cover the light emitting element and the organic layer, and dry etching to form a first reflective layer to be arranged on a side of the organic layer; and forming a third protective layer around (e.g., surrounding) the organic layer and the light emitting elements.

According to one or more embodiments, in the forming of the organic layer and the second protective layer, the organic layer is formed in an island pattern by dry etching utilizing a hard mask on the protective material layer, and the second protective layer having a tip protruding outward from a top surface of the organic layer is formed.

According to one or more embodiments, the first reflective layer is located below the protruding tip.

According to one or more embodiments, the forming of the light emitting element includes: forming a second semiconductor material layer, an active material layer, a first semiconductor material layer, and a conductive material layer on a semiconductor substrate; etching the second semiconductor material layer, the active material layer, the first semiconductor material layer, and the conductive material layer to form light emitting elements each including a second semiconductor layer, an active layer, a first semiconductor layer, and a conductive layer; forming a hole penetrating the conductive layer, the first semiconductor layer, and the active layer in each of the light emitting elements; forming a protective material layer around (e.g., surrounding) each of the light emitting elements and patterning the protective material layer to form a protective film; and forming a mask pattern on the protective film and forming a contact electrode.

According to one or more embodiments, the method further includes: forming a partition wall defining a light emitting area, forming a wavelength conversion layer in a space formed by the partition wall; and forming an overcoat layer and a color filter layer sequentially arranged on the partition wall and the wavelength conversion layer.

According to one or more embodiments of the present disclosure, an electronic device, which displays images, includes a display device for displaying the images, wherein the display device includes: a substrate; a pixel electrode layer on (e.g., arranged on) the substrate; a light emitting element on (e.g., arranged on) the pixel electrode layer and including a contact electrode; an organic layer in an island pattern shape covering a portion of a side surface of the light emitting element and a portion of the pixel electrode layer exposed by the light emitting element; a first reflective layer on (e.g., arranged on) a side surface of the organic layer; and a protective layer protecting the light emitting element, the organic layer, and the first reflective layer.

According to one or more embodiments, the electronic device further includes: a reflective member that reflects an image displayed on the display device; and a display device housing portion housing the display device and the reflective member.

According to one or more embodiments, the electronic device further includes a lens that provides an image reflected from the reflective member (e.g., to one of a user's left eye or right eye).

According to one or more embodiments, the display device is a glasses-type (kind) display device.

According to the display device and the manufacturing method thereof according to one or more embodiments, the amount of light scattered by being emitted toward a lower side of the light emitting element may be reduced. As a result, the panel brightness of the display device may be increased and the power consumption for the same brightness may be reduced.

By reducing the amount of light scattered towards the lower side of the light-emitting element, the display device may achieve a more efficient use of emitted light. This efficiency translates to higher panel brightness without the need for increased power input. Consequently, the display device may maintain enhanced brightness levels while consuming less power. This improvement not only enhances the user experience by providing clearer and brighter displays but also extends the battery life of the device.

The strategic placement of the first reflective layer below the protruding tip of the organic layer plays a role in this light management. The reflective layer redirects light that would otherwise be lost, ensuring that more light is directed towards the display surface. This redirection reduces or minimizes light loss and increases or maximizes the efficiency of the light-emitting elements. The result is a display device that may deliver high brightness and vivid colors with lower energy consumption, making it more environmentally friendly and cost-effective in the long run.

Additionally, the use of micro-light-emitting diode elements, which are made of inorganic materials, contributes to the overall durability and longevity of the display device. These elements are less prone to deterioration compared to their organic counterparts, resulting in a longer lifespan for the display. This durability is particularly important for devices that are subject to frequent use and exposure to various environmental conditions. The combination of high efficiency, low power consumption, and long lifespan makes the display device highly suitable for a wide range of applications, from consumer electronics to industrial displays.

The manufacturing method described herein also allows for the production of thinner and more flexible display panels. By enhancing the arrangement of the light-emitting elements and the reflective layers, the display device can be made more compact without compromising on performance. This flexibility opens up new possibilities for innovative device designs, including foldable and rollable displays, which are becoming increasingly popular in the market. The ability to produce such advanced display technologies further enhances the competitiveness of the display device in the industry.

For example, the display device and its manufacturing method offer improvements in terms of light extraction efficiency, power consumption, durability, and/or design flexibility. These improvements not only enhance the performance and user experience of the display device but also contribute to the development of more sustainable and versatile electronic devices.

However, the effects and benefits of the present disclosure are not limited to the aforementioned effects and benefits, and one or more other effects and benefits are included in the present disclosure.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings.

FIG. 1 is a perspective view illustrating a display device according to one or more embodiments of the present disclosure.

FIG. 2 is a layout diagram illustrating a display device according to one or more embodiments of the present disclosure.

FIG. 3 is a block diagram illustrating a display device according to one or more embodiments of the present disclosure.

FIG. 4 is an equivalent circuit diagram illustrating a sub-pixel according to one or more embodiments of the present disclosure.

FIG. 5 is a layout diagram illustrating pixels of a display area according to one or more embodiments of the present disclosure.

FIG. 6 is a cross-sectional view illustrating an example cross-section of one display panel corresponding to the line I-I′ in FIG. 5 according to one or more embodiments of the present disclosure.

FIG. 7 is a cross-sectional view illustrating an example of the area A1 in FIG. 6 in more detail according to one or more embodiments of the present disclosure.

FIG. 8 is a cross-sectional view illustrating an example of the area A1 of FIG. 6 in more detail according to one or more embodiments of the present disclosure.

FIG. 9 is a cross-sectional view illustrating an example of the area A1 of FIG. 6 in more detail according to one or more embodiments of the present disclosure.

FIG. 10 is a layout diagram illustrating pixels of a display area according to one or more embodiments of the present disclosure.

FIG. 11 is a cross-sectional view illustrating an example of a cross-section of a display panel corresponding to the line I1-I1′ in FIG. 10 according to one or more embodiments of the present disclosure.

FIG. 12 is a cross-sectional view illustrating an example of the area A2 of FIG. 11 in more detail according to one or more embodiments of the present disclosure.

FIG. 13 is a flow chart illustrating a method of manufacturing a display device according to one or more embodiments of the present disclosure.

FIG. 14-26 are explanatory drawings to illustrate a method of manufacturing a display device according to one or more embodiments of the present disclosure.

FIG. 27 is an example view of a smart watch including a display device according to one or more embodiments of the present disclosure.

FIGS. 28 and 29 are example views of a virtual reality (VR) device including a display device according to one or more embodiments of the present disclosure.

FIG. 30 is an example view of a VR device including a display device according to one or more embodiments of the present disclosure.

FIG. 31 is an example view illustrating a vehicle instrument cluster and center fascia including display devices according to one or more embodiments of the present disclosure.

FIG. 32 is an example view of a transparent display device including a display device according to one or more embodiments of the present disclosure.

### DETAILED DESCRIPTION

One or more embodiments of the present disclosure will now be described more fully hereinafter with reference to the accompanying drawings. The embodiments may, however, be provided in different forms and should not be construed as limiting. The same or like reference numbers indicate the same or like components throughout the disclosure. In the accompanying drawings, the thicknesses of layers and regions may be exaggerated for clarity.

Some of the parts which are not associated with the description may not be provided in order to describe embodiments of the disclosure clearly.

It will also be understood that if (e.g., when) a layer is referred to as being “on” another layer or substrate, it may be directly on the other layer or substrate, or one or more intervening layers may also be present therebetween. In contrast, if (e.g., when) an element is referred to as being “directly on” another element, there may be no intervening elements present therebetween.

Further, the phrase “in a plan view” refers to if (e.g., when) an object portion is viewed from above, and the phrase “in a schematic cross-sectional view” refers to if (e.g., when) a schematic cross-section taken by vertically cutting an object portion is viewed from a side. The terms “overlap” or “overlapped” refer to that a first object may be above or below or to a side of a second object, and vice versa. Additionally, the term “overlap” may include layer, stack, face or opposite to (e.g., facing), extending over, covering, or partly covering, or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may refer to that a first object may directly or indirectly oppose a second object. In a case in which a third object intervenes between a first object and a second object, the first object and second object may be understood as being indirectly opposed to each other, although still opposite to (e.g., facing) each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, for example, upside down, the device/element/component positioned “below” or “beneath” another device/element/component may be placed “above” the another device/element/component. Accordingly, the illustrative term “below” may include both (e.g., simultaneously) a lower position and an upper position. In one or more embodiments, the device/element/component may also be oriented in other directions and thus the spatially relative terms may be interpreted differently and accordingly depending on the orientations.

If (e.g., when) an element is referred to as being “connected” or “coupled” to another element, the element may be “directly connected” or “directly coupled” to the another element, or “electrically connected” or “electrically coupled” to the another element with one or more intervening elements interposed therebetween. It will be further understood that if (e.g., when) the terms “comprises,” “comprising,” “has,” “have,” “having,” “includes,” and/or “including” are used, they may specify the presence of stated features, integers, steps, operations, elements, and/or components, but do not preclude the presence or addition of other features, integers, steps, operations, elements, components, and/or any combination thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that, although the terms “first,” “second,” “third,” and/or the like may be used herein to describe one or more suitable elements, these elements should not be limited by these terms. These terms are used to distinguish one element from another element or for the convenience of description and explanation thereof. For example, if (e.g., when) “a first element” is discussed in the description, it may be termed “a second element” or “a third element,” and “a second element” and “a third element” may be termed in a similar manner without departing from the teachings disclosed herein.

The terms “about” or “approximately” as used herein is inclusive of the stated value and refers to within an acceptable range of deviation for the particular value as determined by one of ordinary skill in the art, considering the measurement in question and the error associated with measurement of the particular quantity (for example, the limitations of the measurement system). For example, “about” may refer to within one or more standard deviations, or within ±30%, 20%, 10%, or 5% of the stated value.

In the specification and the claims, the term “and/or” is intended to include any combination of the terms “and” and “or” for the purpose of its meaning and interpretation. For example, “A and/or B” and/or “A/B” may be understood to refer to “A, B, or A and B.” The terms “and” and “or” may be used in the conjunctive or disjunctive sense and may be understood to be equivalent to “and/or.” In the descriptions and the claims, the phrase “at least one of” is intended to include the meaning of “at least one selected from among the group of” for the purpose of its meaning and interpretation. For example, “at least one of A and B,” “at least of A or B,” and/or the like may be understood to refer to “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively (or substantially) formal sense unless clearly defined in the specification.

Hereinafter, specific embodiments will be described with reference to the accompanying drawings.

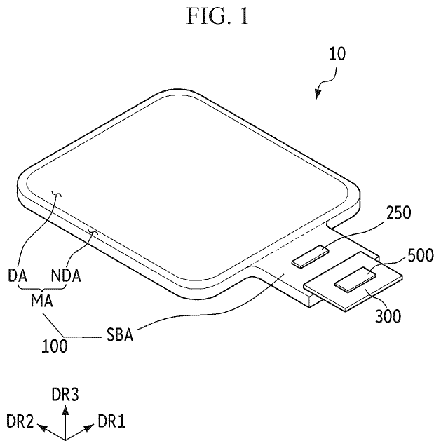

FIG. 1 is a perspective view illustrating a display device according to one or more embodiments of the present disclosure.

Referring to FIG. 1, a display device 10 according to one or more embodiments is a device for displaying video or still images, such as mobile phones, smart phones, tablet personal computers, and/or portable electronic devices such as smart watches, watch phones, mobile communication terminals, electronic notebooks, e-books, portable multimedia players (PMP), navigation, and/or ultra mobile PCs (UMPC), as well as display screens for a variety of products such as televisions, laptops, monitors, billboards, and/or the internet of things (IOT).

In one or more embodiments, the display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, or a miniaturized light-emitting display device utilizing a micro or nano light emitting diode (micro LED or nano LED). Hereinafter, the description focuses on embodiments in which the display device 10 is a micro-light emitting display device, but embodiments of the present disclosure are not limited thereto. In this regard, a micro light emitting diode is referred to as a light emitting element in the following for convenience of explanation.

The display device 10 according to one or more embodiments includes a display panel 100, a display driving circuit 250, a circuit board 300, and a power supply circuit 500.

The display panel 100 may be formed as a rectangular-shaped plane having a short side in a first direction DR1 and a long side in a second direction DR2 that intersects the first direction DR1. A corner where the short side in the first direction DR1 and the long side in the second direction DR2 meet may be rounded to have a set or predetermined curvature or may be formed at a right angle. The planar shape of the display panel 100 is not limited to a rectangle, for example, may be formed in other polygonal shapes, a circular shape, or an oval shape. In one or more embodiments, the display panel 100 may be formed flat, but embodiments of the present disclosure are not limited thereto. For example, in one or more embodiments, the display panel 100 is formed at left and right ends and may include curved portions with a constant curvature or a changing curvature. In one or more embodiments, the display panel 100 may be formed to be flexible, such as to be able to be bent, curved, bent, folded, or rolled.

A substrate of the display panel 100 may include a main area MA and a sub-area SBA.

The main area MA may include a display area DA that displays an image and a non-display area NDA that is a peripheral area of the display area DA. The display area DA may include a plurality of pixels that display an image. For example, in one or more embodiments, the pixel may include a first sub-pixel that is configured to emit first light, a second sub-pixel that is configured to emit second light, and a third sub-pixel that is configured to emit third light.

The sub-area SBA may protrude from a (e.g., one) side of the main area MA in the second direction DR2. Although FIG. 1 illustrates the sub-area SBA being unfolded, in one or more embodiments, the sub-area SBA may be bent, in this regard, the sub-area SBA may be arranged on a bottom surface of the display panel 100. If (e.g., when) the sub-area SBA is bent, it may overlap the main area MA in a third direction DR3, which is a thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method, but embodiments of the present disclosure are not limited thereto. For example, in one or more embodiments, the display driving circuit 250 may be attached to the circuit board 300 using a chip on film (COF) method.

The circuit board 300 may be attached to an (e.g., one) end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. In one or more embodiments, the circuit board 300 may be a flexible film, such as a flexible printed circuit board, a printed circuit board, or a chip on film.

The power supply circuit 500 may generate a plurality of panel driving voltages according to an external power supply voltage. The power supply circuit 500 may be formed as an integrated circuit (IC) and attached to the circuit board 300 using a COF method.

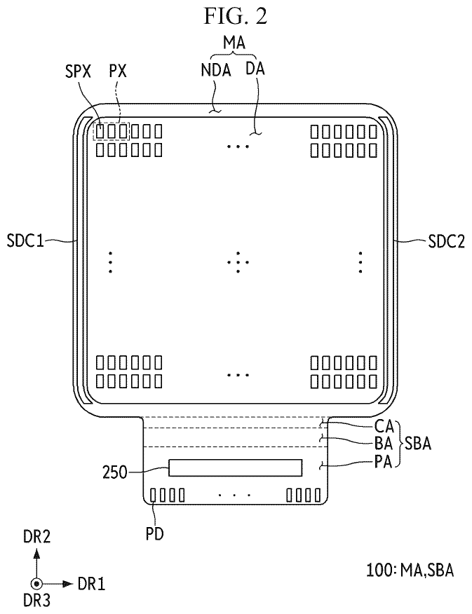

FIG. 2 is a layout diagram illustrating a display device according to one or more embodiments of the present disclosure. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing grayscale (e.g., a white grayscale).

The non-display area NDA may be placed adjacent to the display area DA. The non-display area NDA may be an area outside the display area DA. The non-display area NDA may be arranged to be around (e.g., surround) the display area DA. In one or more embodiments, the non-display area NDA may be an edge area of the display panel 100.

A first scan driving unit SDC1 and a second scan driving unit SDC2 may be arranged in the non-display area NDA. The first scan driving unit SDC1 is arranged on one side (for example, the left side) of the display panel 100, and the second scan driving unit SDC2 is arranged on the other side (for example, the right side) of the display panel 100. However, embodiments of the present disclosure are not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to scan lines.

In one or more embodiments, the sub-area SBA may protrude from one side of the main area MA in the second direction DR2. A length of the sub-area SBA in the second direction DR2 may be smaller than a length of the main area MA in the second direction DR2. A length of the first direction DR1 of the sub-area SBA may be smaller than a length of the first direction DR1 of the main area MA or may be substantially equal to the length of the first direction DR1 of the main area MA. In one or more embodiments, the sub-area SBA may be curved and may be arranged at a lower portion of the display panel 100. In these embodiments, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

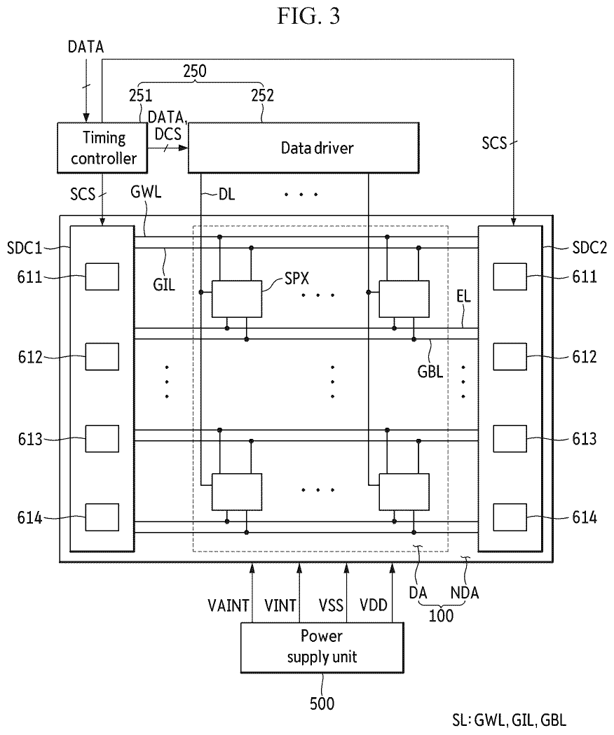

FIG. 3 is a block drawing illustrating a display device according to one or more embodiments of the present disclosure.

Referring to FIG. 2 and FIG. 3, the display area DA includes a plurality of pixels PX including a plurality of sub-pixels SPX, a plurality of scan lines SL, a plurality of emission control lines EL, and a plurality of data lines DL.

The plurality of pixels PX may be arranged in a matrix form along the first direction DR1 and the second direction DR2. For example, in one or more embodiments, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and be arranged along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to a write scan signal of the write scan line GWL and may be to emit light from a light-emitting element according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emitting signal output portion 614. Each of the write scan signal output portion 611, the initialization scan signal output portion 612, the bias scan signal output portion 613, and the light emitting signal output portion 614 may receive a scan timing control signal SCS from a timing controller 251. The write scan signal output portion 611 may generate write scan signals according to the scan timing control signal SCS of the timing controller 251 and sequentially output them to the write scan lines GWL. The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines GBL. The light emitting signal output portion 614 may generate light emitting control signals according to the scan timing control signal SCS and sequentially output them to the emission control lines EL.

The display driving circuit 250 includes the timing controller (e.g., a timing control circuit) 251 and a data driving circuit (i.e., data driver) 252.

The data driving circuit 252 may receive digital video data DATA and a data timing control signal DCS from the timing controller 251. The data driving circuit 252 converts digital video data DATA into analog data voltages according to the data timing control signal DCS and outputs them to the data lines DL. In this regard, the sub-pixels SPX are selected by the write scan signals of the first scan driving unit SDC1 and the second scan driving unit SDC2, and data voltages may be supplied to the selected sub-pixels SPX.

The timing controller 251 may receive digital video data and timing signals from an external source. The timing controller 251 may generate the scan timing control signal SCS and the data timing control signal DCS to control the display panel 100 according to timing signals. The timing controller 251 may output the scan timing control signal SCS to the first scan driving unit SDC1 and the second scan driving unit SDC2. The timing controller 251 may output digital video data DATA and a data timing control signal DCS to the data driving circuit 252.

The power supply unit 500 may generate a plurality of panel driving voltages according to an external power supply voltage. For example, the power supply unit 500 may generate and supply a first driving voltage VDD, a second driving voltage VSS, a third driving voltage VINT, and a fourth driving voltage VAINT to the display panel 100.

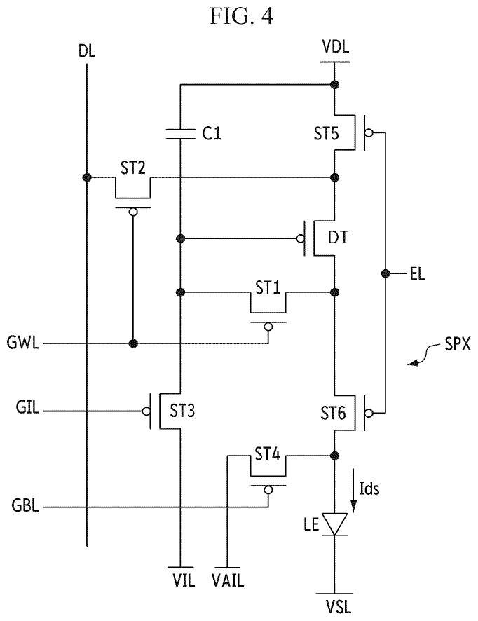

FIG. 4 is an equivalent circuit diagram of a subpixel SPX according to one or more embodiments of the present disclosure.

Referring to FIG. 4, the subpixel SPX according to one or more embodiments may be connected to scan lines GWL, GIL, and GBL, an emission control line EL, and a data line DL. For example, the subpixel SPX may be connected to a write scan line GWL, an initialization scan line GIL, a bias scan line GBL, the emission line EL, and the data line DL.

The subpixel SPX according to one or more embodiments includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light emitting element LE may be a micro light emitting diode (micro-LED).

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power supply line VSL to which a second power supply voltage (e.g., VSS) is applied.

The capacitor C1 is formed between the gate electrode of the driving transistor DT and a first power line VDL to which a first power supply voltage (e.g., VDD) is applied. The first power supply voltage may be at a higher level than the second power supply voltage. One electrode of the capacitor C1 may be connected to the gate electrode of the driving transistor DT, and the other electrode of the capacitor C1 may be connected to the first power line VDL.

As illustrated in FIG. 4, in one or more embodiments, the first through sixth transistors ST1 through ST6 and the driving transistor DT may all be formed as P-type (kind) metal-oxide-semiconductor field effect transistors (MOSFETs). In these embodiments, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors ST5 and ST6 may be connected to the emission line EL. Because the first through sixth transistors ST1 through ST6 are formed as P-type (kind) MOSFETs, they may be turned on if (e.g., when) a scan signal of a gate-low voltage and an emission control signal of a gate-low voltage are transmitted to the initialization scan line GIL, the write scan line GWL, the bias scan line GBL, and the emission line EL. One electrode of the third transistor ST3 and one electrode of the fourth transistor ST4 may be connected to an initialization voltage line VIL or VAIL.

In one or more embodiments, the driving transistor DT, the second transistor ST2, the fourth transistor ST4, the fifth transistor ST5, and the sixth transistor ST6 may be formed as P-type (kind) MOSFETs, and the first transistor ST1 and the third transistor ST3 may be formed as N-type (kind) MOSFETs. The active layer of each of the driving transistor DT, the second transistor ST2, the fourth transistor ST4, the fifth transistor ST5, and the sixth transistor ST6 formed as P-type (kind) MOSFETs may be made of polysilicon, and the active layer of each of the first transistor ST1 and the third transistor ST3 formed as N-type (kind) MOSFETs may be made of an oxide semiconductor.

In these embodiments, because the first transistor ST1 and the third transistor ST3 are formed as N-type (kind) MOSFETs, the first transistor ST1 may be turned on in response to a scan signal of a gate-high voltage, and the third transistor ST3 may be turned on in response to an initialization scan signal of a gate-high voltage. In contrast, because the second transistor ST2, the fourth transistor ST4, the fifth transistor ST5, and the sixth transistor ST6 are formed as P-type (kind) MOSFETs, they may be turned on in response to a scan signal of a gate-low voltage and an emission control signal of a gate-low voltage.

In one or more embodiments, the fourth transistor ST4 may be formed as an N-type (kind) MOSFET. In these embodiments, the active layer of the fourth transistor ST4 may be made of an oxide semiconductor. When the fourth transistor ST4 is formed as an N-type (kind) MOSFET, it may be turned on in response to a scan signal of a gate-high voltage.

In one or more embodiments, the first through sixth transistors ST1 through ST6 and the driving transistor DT may all be formed as N-type (kind) MOSFETs. In these embodiments, the active layer of each of the first through sixth transistors ST1 through ST6 and the driving transistor DT may be made of an oxide semiconductor.

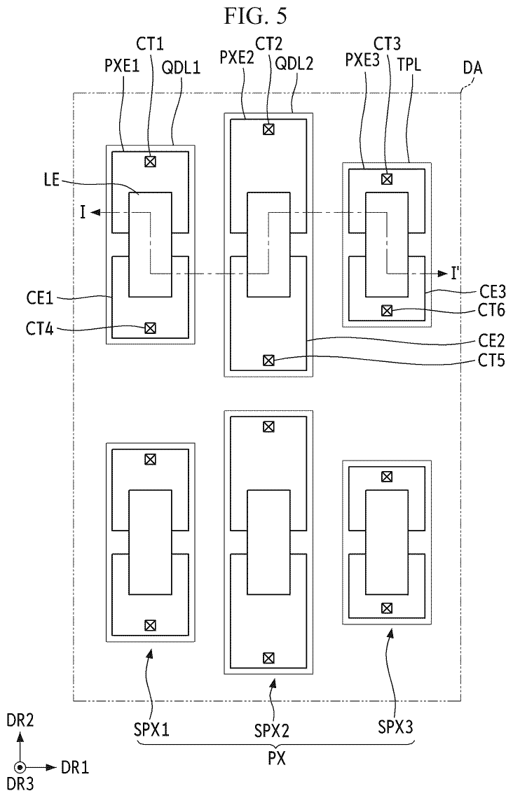

FIG. 5 is a layout diagram illustrating pixels of a display area according to one or more embodiments of the present disclosure.

Referring to FIG. 5, in one or more embodiments, each of the plurality of pixels PX of the display area DA may include three sub-pixels SPX1, SPX2, and SPX3, but embodiments of the present disclosure are not limited thereto, for example, in one or more embodiments, each of the plurality of pixels PX of the display area DA may include four sub-pixels.

The plurality of pixels PX may be arranged in a matrix form. In each of the plurality of pixels PX, the first sub-pixel SPX1, the second sub-pixel SPX2, and the third sub-pixel SPX3 may be arranged in the first direction DR1.

When each of the plurality of pixels PX includes three sub-pixels SPX1, SPX2, and SPX3, the first sub-pixel SPX1 may be to emit light of a first color, the second sub-pixel SPX2 may be to emit light of a second color, and the third sub-pixel SPX3 may be to emit light of a third color. Here, the light of the first color may be light in a blue wavelength band, the light of the second color may be light in a green wavelength band, and the light of the third color may be light in a red wavelength band. For example, the blue wavelength band may refer to light having a main peak wavelength in the wavelength band from approximately 370 nanometers (nm) to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

In one or more embodiments, if (e.g., when) each of the plurality of pixels PX includes four sub-pixels, the first sub-pixel may be to emit light of a first color, the second and fourth sub-pixels may be to emit light of a second color, and the third sub-pixel may be to emit light of a third color. In one or more embodiments, the first sub-pixel may be to emit light of a first color, the second sub-pixel may be to emit light of a second color, the third sub-pixel may be to emit light of a third color, and the fourth sub-pixel may be to emit light of a fourth color. In this regard, the light of the fourth color may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, a plurality of light emitting elements LE, and a second light conversion layer QDL2. The third sub-pixel SPX3 includes a third pixel electrode PXE3, a third common electrode CE3, a plurality of light emitting elements LE, and a light transmission layer TPL.

In each of the first sub-pixel SPX1, the second sub-pixel SPX2, and the third sub-pixel SPX3, the pixel electrodes PXE1, PXE2, and PXE3 and the respective common electrodes CE1, CE2, and CE3 may be arranged in the second direction DR2. In one or more embodiments, each of the pixel electrodes PXE1, PXE2, and PXE3 and the common electrodes CE1, CE2, and CE3 may have a rectangular plane shape, but embodiments of the present disclosure are not limited thereto. In one or more embodiments, an area of the first pixel electrode PXE1 may be substantially the same as an area of the first common electrode CE1, an area of the second pixel electrode PXE2 may be substantially the same as an area of the second common electrode CE2, and an area of the third pixel electrode PXE3 may be substantially the same as an area of the third common electrode CE3, but embodiments of the present disclosure are not limited thereto.

For example, as shown in FIG. 5, if (e.g., when) the light conversion efficiency of the second light conversion layer QDL2 is lower than the light conversion efficiency of the first light conversion layer QDL1, the area of the second pixel electrode PXE2 may be larger than the area of the first pixel electrode PXE1.

Furthermore, while the light transmission layer TPL directly transmits the light of the light emitting element LE, the first light conversion layer QDL1 need to convert the light, and therefore the area of the first pixel electrode PXE1 may be larger than the area of the third pixel electrode PXE3 and the area of the first common electrode CE1 may be larger than the area of the third common electrode CE3.

Each of the pixel electrodes PXE1, PXE2, and PXE3 may be electrically connected to at least one transistor through respective pixel connection hole CT1, CT2, or CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to a second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

A plurality of light emitting elements LE may be arranged on the pixel electrodes PXE1, PXE2, and PXE3 and the common electrode CE1, CE2, and CE3. In one or more embodiments, each of the plurality of light emitting elements LE may have a rectangular planar shape, but embodiments of the present disclosure are not limited thereto. For example, in one or more embodiments, each of the plurality of light emitting elements LE may have a circular planar shape.

The first light conversion layer QDL1 may completely overlap with the plurality of light emitting elements LE of the first sub-pixel SPX1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the plurality of light emitting elements LE of the second sub-pixel SPX2. An area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift the third light emitted from the plurality of light emitting elements LE of the second sub-pixel SPX2 into the second light.

The light transmission layer TPL may completely overlap the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

In one or more embodiments, if (e.g., when) the light emitting element LE of the first sub-pixel SPX1 emits light of a first color, the light emitting element LE of the second sub-pixel SPX2 emits light of a second color, and the light emitting element LE of the third sub-pixel SPX3 emits light of a third color, the light conversion layers QDL1 and QDL2 and the light transmission layer TPL may not be provided.

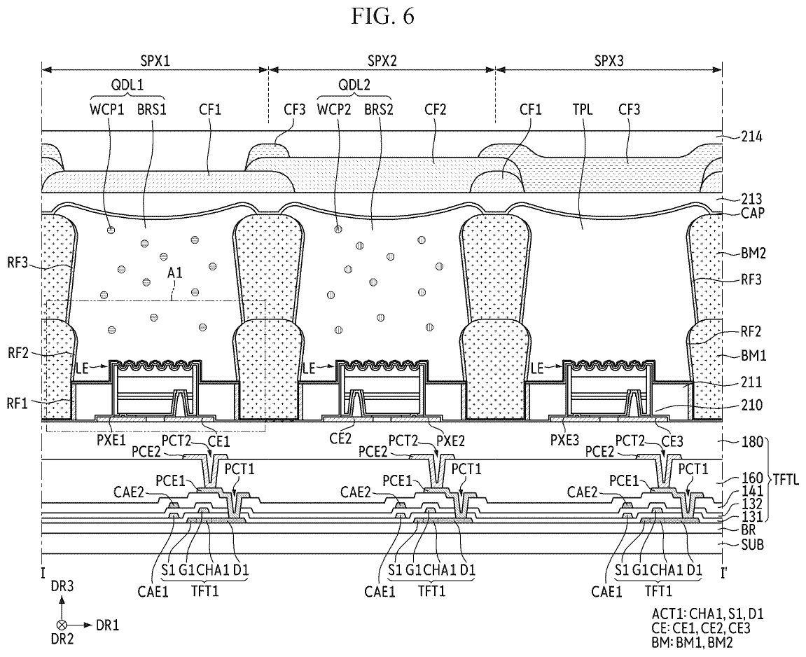

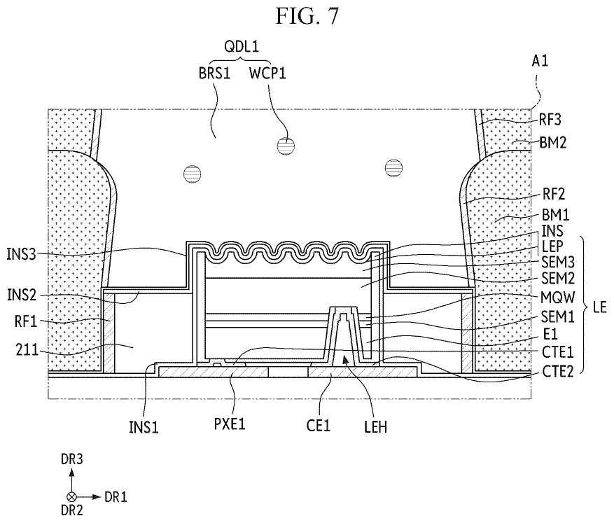

FIG. 6 is a cross-sectional view illustrating an example cross-section of one display panel corresponding to the lines I-I′ in FIG. 5 according to one or more embodiments of the present disclosure. FIG. 7 is a cross-sectional view illustrating an example of the area A1 in FIG. 6 in more detail according to one or more embodiments of the present disclosure.

Referring to FIG. 6 to FIG. 7, a substrate SUB may be made of an insulating material such as glass, polymer resin, and/or the like. If (e.g., when) the substrate SUB is made of a polymer resin, it may be a flexible substrate that may be stretched. The polymer resin may be an acrylic resin, an epoxy resin, a phenolic resin, a polyamide resin, a polyimide resin, and/or the like.

A barrier film BR may be arranged on the substrate SUB. The barrier film BR is a film that protects transistors of a thin film transistor layer TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. In one or more embodiments, the first active layer ACT1 of the thin film transistor TFT1 may include polycrystalline silicon, monocrystalline silicon, low-temperature polycrystalline silicon, or amorphous silicon. In one or more embodiments, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin film transistor TFT1.

A first gate metal layer may be arranged on the first gate insulating film 131. The first gate metal layer may include the first gate electrode G1 of the thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart from each other in FIG. 6, in one or more embodiments, the first gate electrode G1 and the first capacitor electrode CAE1 may be connected to each other.

A second gate insulating film 132 may be arranged on the first gate electrode G1 of the thin film transistor TFT1 and the first capacitor electrode CAE1.

A second gate metal layer may be arranged on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a set or predetermined dielectric constant, a capacitor (e.g., C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization organic film 160 may be arranged on the first source connection electrode PCE1 to planarize a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2.

The barrier film BR, the first gate insulating film 131, the second gate insulating film 132, and the first interlayer insulating film 141 may each be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may each be formed as a single layer or multiple layers of any one selected from among molybdenum (Mo), aluminum (Al), chromium (Cr), gold (Au), titanium (Ti), nickel (Ni), neodymium (Nd), and copper (Cu), or of an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, PXE3, light emitting elements LE, a common electrode CE (i.e., CE1, CE2, CE3), and an organic layer 210.

A pixel electrode layer including pixel electrodes PXE1, PXE2, and PXE3 and common electrodes CE1, CE2, and CE3 may be arranged on a second planarization organic film 180.

Each of the first pixel electrode PXE1, the second pixel electrode PXE2, and the third pixel electrode PXE3 may be connected to a second source connection electrode PCE2 through a respective connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled or selected by the thin film transistor TFT1 may be applied to each of the pixel electrodes PXE1, PXE2, and PXE3.

The common electrodes CE1, CE2, and CE3 may each be connected to a second power supply line (VSL in FIG. 4) to which a second driving voltage (VSS in FIG. 3) is applied through a common connection hole (CT4/CT5/CT6 in FIG. 5). For example, the first common electrode CE1 may be connected to the second power supply line VSL through the second common connection hole CT4. The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one selected from among molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) having low surface resistance to lower the resistance of each of the pixel electrodes PXE1, PXE2, and PXE3.

A light emitting element LE may be arranged on each pixel electrode layer.

In FIG. 6 and FIG. 7, the light emitting element LE is illustrated as a flip-type (kind) micro LED. The flip-type (kind) micro LED refers to an LED in which contact electrodes CTE1 and CTE2 are formed on one side (e.g., a bottom side) of the light emitting element LE.

Each of the plurality of light emitting elements LE may be formed from an inorganic material such as gallium nitride (GaN).

In one or more embodiments, each of the plurality of light emitting elements LE may be formed by growing on a semiconductor substrate such as a silicon substrate and/or a sapphire substrate. The plurality of light emitting elements LE may be transferred onto the pixel electrode layer of the display panel 100 directly from the semiconductor substrate or through a relay substrate. In one or more embodiments, the plurality of light emitting elements LE may be transferred onto the pixel electrodes PXE1, PXE2, and PXE3 of the display panel 100 through an electrostatic method using an electrostatic head or a stamp method using an elastic polymer material such as polydimethylsiloane (PDMS) or silicone as a relay substrate.

In one or more embodiments, a reflective layer may be arranged on a top surface of the pixel electrode PXE1 and a top surface of the common electrode CE1.

The reflective layer may reflect light traveling downward from the light emitting element LE and emit light to a top surface of the light emitting element LE. Therefore, because the light loss of the light emitting element LE may be reduced, the light efficiency of the light emitting element LE may be increased.

The reflective layer may be formed as a single layer of a metal having high reflectivity or may be formed as a multilayer such as titanium (Ti)/aluminum (Al)/titanium (Ti) or ITO/aluminum (Al)/ITO.

The light emitting element LE may include a conductive layer E1, a first semiconductor layer SEM1, an active layer MQW, a second semiconductor layer SEM2, a third semiconductor layer SEM3, a first contact electrode CTE1, a second contact electrode CTE2, and a protective layer (i.e., a protective film) INS.

The conductive layer E1 may be arranged on a bottom surface of the first semiconductor layer SEM1. The conductive layer E1 may include one selected from among molybdenum (Mo), aluminum (Al), chromium (Cr), gold (Au), titanium (Ti), nickel (Ni), neodymium (Nd), and copper (Cu).

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), and/or the like, such as gallium nitride (GaN).

The active layer MQW may be arranged on the first semiconductor layer SEM1. The active layer MQW may be to emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In one or more embodiments, the well layer may be formed of indium gallium nitride (InGaN), and the barrier layer may be formed of gallium nitride (GaN) and/or aluminum gallium nitride (AlGaN), but embodiments of the present disclosure are not limited thereto.

In one or more embodiments, the active layer MQW may have a structure in which semiconductor materials having a high band gap energy and semiconductor materials having a low band gap energy are alternately stacked with each other, may include other Group three (III) to five (V) semiconductor materials according to the wavelength range of emitted light.

For example, if (e.g., when) the active layer MQW includes InGaN, the color of the emitted light may vary depending on the content (e.g., amount) of indium (In). For example, as the content (e.g., amount) of indium (In) increases, the wavelength band of light emitted by the active layer may shift to the red wavelength band, and as the content (e.g., amount) of indium (In) decreases, the wavelength band of light emitted by the active layer may shift to the blue wavelength band. For example, the content (e.g., amount) of indium (In) in the active layer MQW of the light emitting element LE that emits the third light (light in the blue wavelength band) may be approximately (about) 10 wt % to (about) 20 wt %.

The second semiconductor layer SEM2 may be arranged on the active layer MQW. The second semiconductor layer SEM2 may be a semiconductor material layer doped with a second conductive dopant such as silicon (Si), germanium (Ge), tin (Sn), and/or the like, for example gallium nitride (GaN).

The third semiconductor layer SEM3 may be arranged on the second semiconductor layer SEM2. The third semiconductor layer SEM3 may be a semiconductor material layer in which an N-type (kind) dopant is lower than a set or predetermined threshold value and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN), where the N-type (kind) dopant is lower than a set or predetermined threshold value.

A top surface of the third semiconductor layer SEM3 may have a light extraction pattern LEP.

The light extraction patterns LEP may be patterns for increasing the efficiency of light emitted from the top surface of the light emitting element LE. The light extraction patterns LEP may be concave patterns formed in a hemisphere or a semi-ellipse. The light extraction patterns LEP may be concave patterns having a cross-sectional shape of a semicircle or a semi-ellipse.

In one or more embodiments, an electron blocking layer may be arranged between the first semiconductor layer SEM1 and the active layer MQW. The electron blocking layer may be a layer to suppress or prevent or reduce too many electrons from flowing into the active layer MQW. For example, the electron blocking layer may be aluminum gallium nitride (AlGaN) or P-type (kind) aluminum gallium nitride (AlGaN) doped with p-type (kind) magnesium (Mg). In one or more embodiments, the electronic blocking layer may not be provided.

In one or more embodiments, a superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or P-type (kind) aluminum gallium nitride (AlGaN) doped with p-type (kind) magnesium (Mg). In one or more embodiments, the superlattice layer may not be provided.

The protective layer INS may be a film for protecting a bottom surface and side surfaces of the light emitting element LE. The protective layer INS may be arranged on a bottom surface and side surfaces of the conductive layer E1 and side surfaces of a plurality of semiconductor layers SEM1, MQW, SEM2, and SEM3. The protective layer INS may be formed of an inorganic film, such as silicon nitride (SiNₓ), silicon oxide nitride (SiON), silicon oxide (SiOₓ), titanium oxide (TiOₓ), and/or aluminum oxide (AlOₓ). The protective layer INS may be arranged from one end to the other end of the side surface of the light emitting element LE but may be arranged to be spaced and/or apart (e.g., spaced apart or separated) from one end due to a process error.

A hole LEH may be formed to penetrate the conductive layer E1, the first semiconductor layer SEM1, and the active layer MQW of the light emitting element LE to expose the second semiconductor layer SEM2. In one or more embodiments, the hole LEH may have a rectangular planar shape, but embodiments of the present disclosure are not limited thereto. For example, in one or more embodiments, the hole LEH may have a polygonal planar shape, a circle shape, an oval shape, or a square shape.

In addition, the protective layer INS may be arranged on a sidewall of the conductive layer E1, a sidewall of the first semiconductor layer SEM1, and a sidewall of the active layer MQW, each exposed in the hole LEH. The protective layer INS may not cover the second semiconductor layer SEM2 in the hole LEH. Therefore, the second semiconductor layer SEM2 may be exposed without being covered by the protective layer INS.

The first contact electrode CTE1 may be arranged on a bottom surface of the conductive layer E1. The first contact electrode CTE1 may be arranged on the bottom surface of the conductive layer E1 that is exposed and not covered by the protective layer INS. Therefore, the first contact electrode CTE1 may be electrically connected to the conductive layer E1.

The second contact electrode CTE2 may be arranged on at least one side and the bottom surface of the conductive layer E1. In this regard, the first contact electrode CTE1 may be arranged on a first side of the semiconductor stack (i.e., SEM1, MQW, SEM2, and SEM3) and a first side of the conductive layer E1, while the second contact electrode CTE2 may be arranged on a second side of the semiconductor stack and a second side of the conductive layer E1.

The second contact electrode CTE2 may be arranged on the protective layer INS arranged in the hole LEH and the second semiconductor layer SEM2 exposed in the hole LEH without being covered by the protective layer INS. Therefore, the second contact electrode CTE2 may be electrically connected to the second semiconductor layer SEM2 in the hole LEH.

The first contact electrode CTE1 and the second contact electrode CTE2 may each independently include at least one selected from among molybdenum (Mo), aluminum (Al), chromium (Cr), gold (Au), titanium (Ti), nickel (Ni), neodymium (Nd), and copper (Cu). For example, in one or more embodiments, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

A first protective layer INS1 may be arranged to cover all the pixel electrodes PXE1, PXE2, and PXE3 and the common electrodes CE1, CE2, and CE3 and the light emitting elements LE arranged thereon. The first protective layer INS1 may also cover all the pixel electrodes PXE1, PXE2, and PXE3 and the common electrodes CE1, CE2, and CE3 on which the light emitting elements LE are not arranged.

A first organic layer 211 may be arranged on the first protective layer INS1 on which the light emitting elements LE are not arranged. For example, the first organic layer 211 may overlap at least a portion of the pixel electrodes PXE1, PXE2, and PXE3 and at least a portion of the common electrodes CE1, CE2, and CE3. The first organic layer 211 may be arranged to cover a portion of the side surfaces of the plurality of light emitting elements LE. Therefore, the first organic layer 211 may serve to fix the light emitting elements LE. For example, the first organic layer 211 may cover the side surfaces of the conductive layer E1, the first semiconductor layer SEM1, and the active layer MQW of the plurality of light emitting elements LE and may cover at least a portion of the side surface of the second semiconductor layer SEM2. The top surface of each of the plurality of light emitting elements LE may be exposed without being covered by the first organic layer 211.

In one or more embodiments, the first organic layer 211 may be arranged in an island pattern shape in each sub-pixel SPX1, SPX2, and SPX3. For example, the first organic layer 211 arranged in each sub-pixel SPX1, SPX2, and SPX3 may be arranged spaced and/or apart (e.g., spaced apart or separated) from the first organic layer 211 arranged in the adjacent sub-pixel SPX1, SPX2, and SPX3. For example, the first organic layer 211 may be arranged in an island shape around each sub-pixel SPX1, SPX2, and SPX3.

The first organic layer 211 may be formed of an organic film such as an acrylic resin, an epoxy resin, a phenolic resin, a polyamide resin, a polyimide resin, and/or the like.

A first reflective layer RF1 may be arranged on a side surface of the first organic layer 211.

The first reflective layer RF1 may be arranged from a bottom to a top surface of the first organic layer 211. For example, one end of the first reflective layer RF1 may be arranged on the second planarized organic film 180, and the other end of the first reflective layer RF1 may be arranged on a same plane as the top surface of the first organic layer 211. The first reflective layer RF1 may include a metal material having a high reflectivity, such as aluminum (Al).

The first reflective layer RF1 surrounds the side surface of the first organic layer 211, thereby around (e.g., surrounding) the active layer MQW of the light emitting element LE. Thus, the first reflective layer RF1 may minimize or reduce the loss caused by the light being emitted from the active layer MQW to the side and scattered. Accordingly, the display device according to one or more embodiments may increase the luminance of the display device when a same current is injected as conventionally. Furthermore, the display device according to one or more embodiments may reduce the power consumption compared to a same luminance as conventionally.

A second protective layer INS2 may be arranged to cover an upper portion of the first organic layer 211 and the entire light emitting element LE that is not covered by the first organic layer 211 and is exposed by the first organic layer 211. The second protective layer INS2 may not cover the side of the first organic layer 211. The second protective layer INS2 may be arranged on the other end of the first reflective layer RF1.

A third protective layer INS3 may cover an upper portion of the second protective layer INS2 and be around (e.g., surround) the side of the first reflective layer RF1. Further, the third protective layer INS3 may be arranged on the first protective layer INS1 on which the first organic layer 211 is not arranged. The third protective layer INS3 may overlap a first partition wall BM1 described below in the third direction DR3.

The first protective layer INS1, the second protective layer INS2, and the third protective layer INS3 may each be formed of an inorganic film, for example, silicon nitride (SiNₓ), silicon oxide (SiON), silicon oxide (SiOₓ), titanium oxide (TiOₓ), and/or aluminum oxide (AlOₓ).

Because an upper portion of the first reflection layer RF1 is surrounded by the second protective layer INS2, a side surface of the first reflective layer RF1 is surrounded by the third protective layer INS3, and a bottom surface of the first reflection layer RF1 is surrounded by the first protective layer INS1, the first reflective layer RF1 may be surrounded by the protective layer.

On the third protective layer INS3, partition walls BM1 and BM2 may be further arranged to compartmentalize each sub-pixel SPX1, SPX2, and SPX3.

The partition walls BM1 and BM2 may also be referred to as a light blocking layer in that it includes a light blocking material to prevent or reduce light from a light emitting element LE of a sub-pixel from traveling to an adjacent sub-pixel.

The partition walls BM1 and BM2 may be formed in a grid-shaped pattern throughout the entire display area (DA in FIG. 1). The partition walls BM1 and BM2 may not overlap a plurality of light emitting elements LE in the third direction DR3. The partition walls BM1 and BM2 may serve to provide a space for forming a first light conversion layer QDL1, a second light conversion layer QDL2, and a light transmission layer TPL. The partition walls BM1 and BM2 may each be formed from organic insulating materials such as an acrylic resin, an epoxy resin, a phenolic resin, a polyamide resin, a polyimide resin, and/or the like.

In one or more embodiments, the partition walls BM1 and BM2 are formed as a single layer, but embodiments of the present disclosure are not limited thereto. For example, in one or more embodiments, the partition walls BM1 and BM2 may be formed as two layers. The partition walls BM1 and BM2 may be formed as two layers to sufficiently secure a space for forming the first light conversion layer QDL1, the second light conversion layer QDL2, and the light transmission layer TPL.

The partition walls BM1 and BM2 may each include a light blocking material. For example, the partition walls BM1 and BM2 may each include an inorganic black pigment such as carbon black and/or an organic black pigment.

Reflective layers RF2 and RF3 may be arranged inside a space formed by the partition walls BM1 and BM2. The reflective layers RF2 and RF3 may be arranged on a side surface of the partition walls BM1 and BM2, a bottom surface between the partition walls BM1 and BM2 and the partition walls BM1 and BM2 that does not overlap with the pixel electrodes PXE1, PXE2, and PXE3, the common electrode CE, and the light emitting element LE. The reflective layers RF2 and RF3 may include an opening formed in an area that overlaps with the pixel electrodes PXE1, PXE2, and PXE3, the common electrode CE, and the light emitting element LE. The reflective layers RF2 and RF3 may not be in contact with the pixel electrodes PXE1, PXE2, and PXE3 and the common electrode CE, and may not be electrically connected to them.

The reflective layers RF2 and RF3 serve to reflect light traveling in the lateral direction from the first light conversion layer QDL1, the second light conversion layer QDL2, and the light transmission layer TPL.

The reflective layers RF2 and RF3 may include a metal material having a high light reflectivity. For example, in one or more embodiments, the reflective layers RF2 and RF3 may include aluminum or silver and may also include an alloy thereof.

In the first sub-pixel SPX1, the first light conversion layer QDL1 may be arranged between the partition wall BM (i.e., BM1 and BM2) and the partition wall BM, in the second sub-pixel SPX2, the second light conversion layer QDL2 may be arranged between the partition wall BM and the partition wall BM, and in the third sub-pixel SPX3, the light transmission layer TPL may be arranged between the partition wall BM and the partition wall BM.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into the first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into the second light (light in the green wavelength band).

The light transmission layer TPL may include a light-transmitting organic material.

For example, the first base resin BRS1, the second base resin BRS2, and the light transmission layer TPL may each independently include an epoxy-based resin, an acrylic-based resin, a cado-based resin, and/or an imide-based resin. The first and second wavelength conversion particles WCP1 and WCP2 may be quantum dots (QD), quantum rods, fluorescent materials, and/or phosphorescent materials.

A capping layer CAP may be arranged on the partition wall BM, the first light conversion layer QDL1, the second light conversion layer QDL2, and the light transmission layer TPL.

The capping layer CAP may be formed of an inorganic film, such as silicon nitride (SiNₓ), silicon oxide nitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the capping layer CAP.

A fourth organic film 213 may be arranged on the capping layer CAP. A plurality of color filters CF1, CF2, and CF3 may be arranged on the fourth organic film 213. The plurality of color filters CF1, CF2, and CF3 may include first color filters CF1, second color filters CF2, and third color filters CF3.

The first color filter CF1 arranged in the first sub-pixel SPX1 may be to transmit the first light (light in the red wavelength band) and absorb or block the third light (light in the blue wavelength band). Therefore, the first color filter CF1 may be to transmit the first light (light in the red wavelength band) that has been converted by the first light conversion layer QDL1 among the third light (light in the blue wavelength band) emitted from the light emitting element LE and absorb or block the third light (light in the blue wavelength band) that has not been converted by the first light conversion layer QDL1. Accordingly, the first sub-pixel SPX1 may be to emit the first light (light in the red wavelength band).

The second color filter CF2 arranged in the second sub-pixel SPX2 may be to transmit the second light (light in the green wavelength band) and absorb or block the third light (light in the blue wavelength band). Therefore, the second color filter CF2 may be to transmit the second light (light in the green wavelength band) that has been converted by the second light conversion layer QDL2 among the third light (light in the blue wavelength band) emitted from the light emitting element LE and absorb or block the third light (light in the blue wavelength band) that has not been converted by the second light conversion layer QDL2. Accordingly, the second sub-pixel SPX2 may be to emit the second light (light in the green wavelength band).

The third color filter CF3 arranged in the third sub-pixel SPX3 may be to transmit the third light (light in the blue wavelength band). Therefore, the third color filter CF3 may be to transmit the third light (light in the blue wavelength band) emitted from the light emitting element LE passing through the light transmission layer TPL. Accordingly, the third sub-pixel SPX3 may be to emit the third light (light in the blue wavelength band).

The first color filter CF1, the second color filter CF2, and the third color filter CF3 overlapping in the third direction DR3 may overlap with the partition walls BM1 and BM2 in the third direction DR3.

A fifth organic film 214 for planarization may be arranged on the plurality of color filters CF1, CF2, and CF3.

The fourth organic film 213 and the fifth organic film 214 may each be formed from an acrylic resin, an epoxy resin, a phenolic resin, a polyamide resin, a polyimide resin, and/or the like.

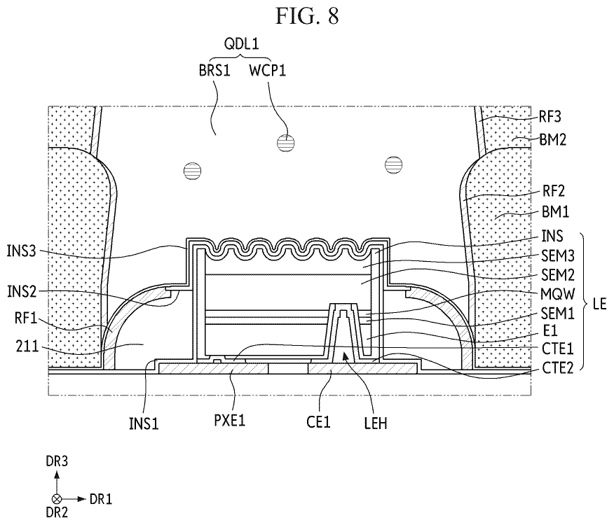

FIG. 8 is a cross-sectional view illustrating an example of the area A1 of FIG. 6 in more detail according to one or more embodiments of the present disclosure.

The embodiment of FIG. 8 differs from the embodiment of FIG. 7 in that the first organic layer 211 is dome-shaped. In FIG. 8, descriptions that overlap with the embodiment of FIG. 7 will not be provided, and only differences from the embodiment of FIG. 7 will be mainly described.

The first organic layer 211 may be arranged to cover a portion of the side surfaces of the plurality of light emitting elements LE. Further, the first organic layer 211 may be arranged to cover the pixel electrodes PXE1, PXE2, and PXE3 and the common electrodes CE1, CE2, and CE3 covered by the first protective layer INS1.

The first organic layer 211 may be a dome-shaped structure that narrows toward the top from the side surface of the light emitting element LE. For example, the first organic layer 211 may cover the side surfaces of the conductive layer E1, the first semiconductor layer SEM1, and the active layer MQW of the plurality of light emitting elements LE, and at least a portion of the side surface of the second semiconductor layer SEM2. The top surface of each of the plurality of light emitting elements LE may be exposed without being covered by the first organic layer 211.

In one or more embodiments, the first organic layer 211 may be arranged in an island pattern shape in each sub-pixel SPX1, SPX2, and SPX3. For example, the first organic layer 211 arranged in each sub-pixel SPX1, SPX2, and SPX3 may be arranged spaced and/or apart (e.g., spaced apart or separated) from the first organic layer 211 arranged in the adjacent sub-pixel SPX1, SPX2, and SPX3. For example, the first organic layer 211 may be arranged in an island shape around each sub-pixel SPX1, SPX2, and SPX3.

The first reflective layer RF1 may be arranged on a dome-shaped side of the first organic layer 211.

In one or more embodiments, the first partition wall BM1 does not overlap the first organic layer 211, but embodiments of the present disclosure are not limited thereto. In one or more embodiments, the first partition wall BM1 may overlap a portion of the first organic layer 211. In these embodiments, at least a portion of the first reflective layer RF1 arranged on the side of the first organic layer 211 may overlap the first partition wall BM1.

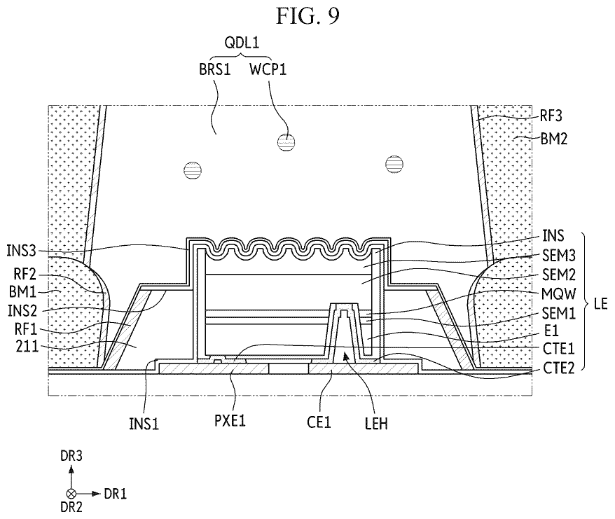

FIG. 9 is a cross-sectional view illustrating an example of the area A1 of FIG. 6 in more detail according to one or more embodiments of the present disclosure.

The embodiment of FIG. 9 differs from the embodiment of FIG. 7 in that the side surface of the first organic layer 211 has an acute angle of inclination. In FIG. 9, descriptions that overlap with the embodiment of FIG. 7 will not be provided, and only differences from the embodiments of FIG. 7 will be mainly described.

The side surface of the first organic layer 211 may have an inclination angle of about 55° to about 85° relative to the bottom surface of the first organic layer 211.

Accordingly, the first reflective layer RF1 may also have an inclination angle of about 55° to about 85°.

The first organic layer 211 may have a tapered shape that gradually narrows as it goes upward in a thickness direction of the display device. When the side surface of the first organic layer 211 is formed in a tapered shape, the light emission efficiency may increase.

In one or more embodiments, the side surface of the first organic layer 211 may be formed in a reverse tapered shape that gradually widens as it goes upward to achieve the effect of widening the viewing angle.

In the context of the present disclosure and unless defined otherwise, “gradually” refers to a slow and steady change in the shape of the first organic layer 211 as it goes upward. Specifically, the layer narrows slowly and steadily as it increases in thickness, forming a tapered shape. Alternatively, the layer may widen slowly and steadily as it goes upward, forming a reverse tapered shape. This gradual change in shape is intended to improve light emission efficiency or widen the viewing angle of the display device. For example, “gradually” means changing in small, consistent increments over a period of time. For example, there are no sudden changes in the shape; instead, the change happens smoothly and progressively.

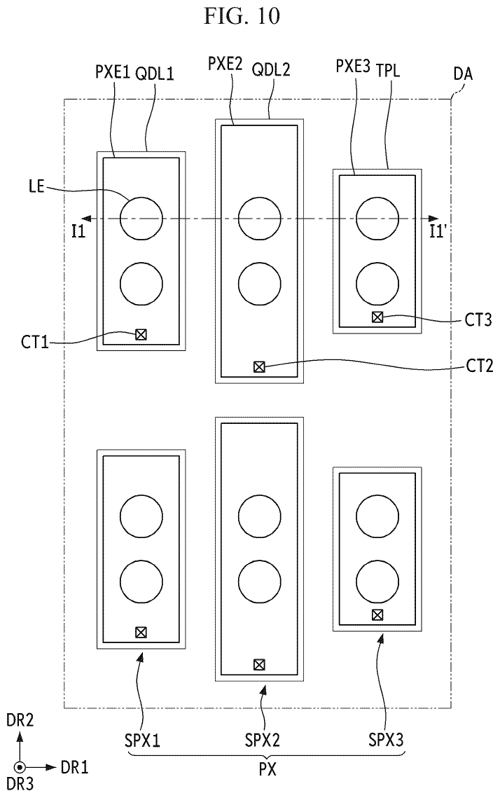

FIG. 10 is a layout diagram illustrating pixels of a display area according to one or more embodiments of the present disclosure.

The embodiment of FIG. 10 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In the embodiment of FIG. 10, the description overlapping with the embodiment of FIG. 5 will not be provided.

Referring to FIG. 10, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

In one or more embodiments, each of the first pixel electrode PXE1, the second pixel electrode PXE2, and the third pixel electrode PXE3 may have a rectangular planar shape having a short side in the first direction DR1 and a long side in the second direction DR2. An area of the first sub-pixel SPX1, an area of the second sub-pixel SPX2, and an area of the third sub-pixel SPX3 may be set according to the light conversion efficiency of the first light conversion layer QDL1 and the light conversion efficiency of the second light conversion layer QDL2. For example, the area of the sub-pixel may be larger as the light conversion efficiency is lower.

For example, as shown in FIG. 10, if (e.g., when) the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light emitting element LE, while the first light conversion layer QDL1 needs to convert the light, the area of the first pixel electrode PXE1 may be larger than the area of the third pixel electrode PXE3.

Each of the pixel electrodes PXE1, PXE2, and PXE3 may be electrically connected to at least one transistor through a respective pixel connection hole CT1, CT2, or CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The plurality of light emitting elements LE may be arranged on each of the pixel electrodes PXE1, PXE2, and PXE3. In one or more embodiments, the same number of light emitting elements LE may be arranged on each of the pixel electrodes PXE1, PXE2, and PXE3. For example, in one or more embodiments, two light emitting elements LE may be arranged on each of the pixel electrodes PXE1, PXE2, and PXE3.

The first light conversion layer QDL1 may completely overlap the plurality of light emitting elements LE of the first pixel electrode PXE1 and the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the second pixel electrode PXE2 and the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift third light emitted from the plurality of light emitting elements LE of the second sub-pixel SPX2 into second light.

The light transmission layer TPL may completely overlap with the third pixel electrode PXE3 and the plurality of light emitting elements LE of the third sub-pixel SPX3. The light transmission layer TPL may directly transmit the incident light. For example, the light transmission layer TPL may directly transmit third light emitted from the plurality of light emitting elements LE of the third sub-pixel SPX3.

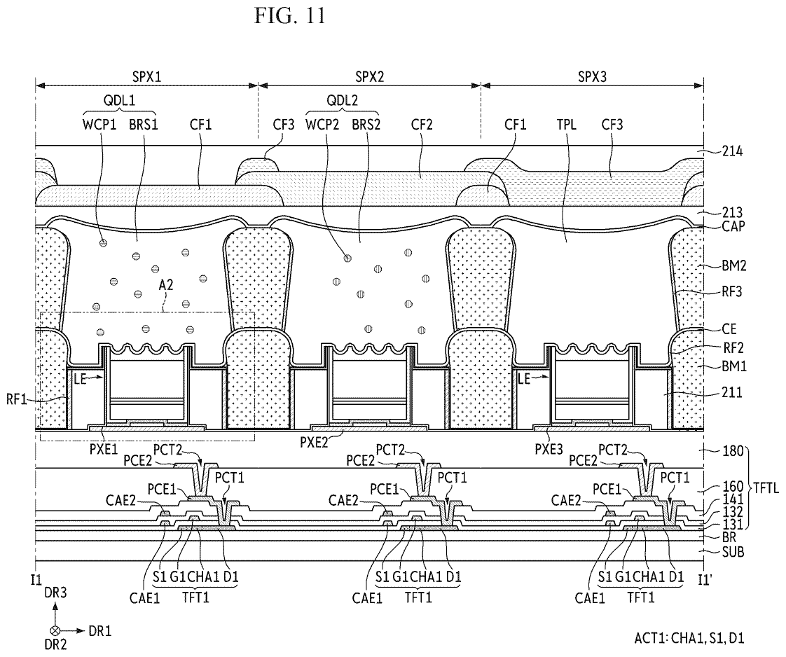

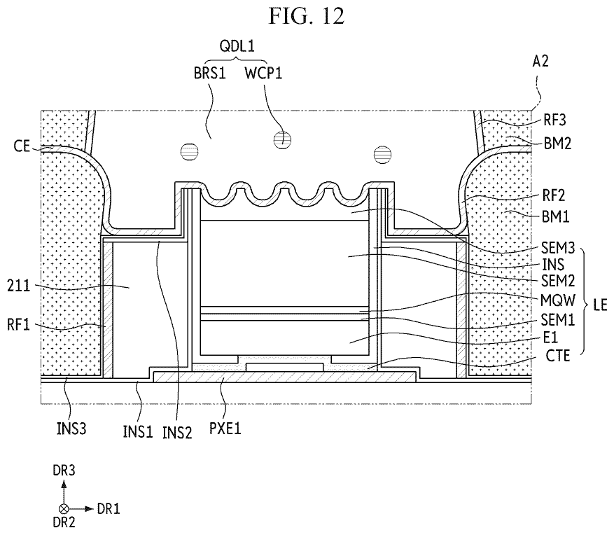

FIG. 11 is a cross-sectional view illustrating an example of a cross-section of a display panel corresponding to the line I1-I1′ in FIG. 10 according to one or more embodiments of the present disclosure. FIG. 12 is a cross-sectional view illustrating one example of the area A2 of FIG. 11 in more detail according to one or more embodiments.

The embodiments of FIG. 11 and FIG. 12 differ from the embodiment of FIG. 6 in that the light emitting elements LE are vertical type (kind) micro LED in which each of the plurality of light emitting elements LE extends in the third direction DR3. The vertical type (kind) micro LED refers to an LED having a structure in which a first semiconductor layer SEM1, an active layer MQW, a second semiconductor layer SEM2, and a third semiconductor layer SEM3 are sequentially arranged in the third direction DR3, which is a vertical direction.

In one or more embodiments of FIG. 11 and FIG. 12, descriptions that overlap with those of one or more embodiments of FIG. 6 and FIG. 7 will not be repeated for conciseness.

Referring to FIG. 11 and FIG. 12, a pixel electrode layer may be arranged on the second planarization organic film 180. The pixel electrode layer may include a first pixel electrode PXE1, a second pixel electrode PXE2, and a third pixel electrode PXE3.

In one or more embodiments, a reflective layer may be arranged on a top surface of each of the first pixel electrode PXE1, the second pixel electrode PXE2, and the third pixel electrode PXE3.

The reflective layer may reflect light traveling downward from the light emitting element LE and emit light to the top surface of the light emitting element LE. Therefore, because the loss of light from the light emitting element LE may be reduced, the light efficiency of the light emitting element LE may be increased.

The light emitting elements LE are arranged on the first pixel electrode PXE1, the second pixel electrode PXE2, and the third pixel electrode PXE3.

Each of the plurality of light emitting elements LE may have a length in the first direction DR1, a length in the second direction DR2, and a length in the third direction DR3 of several μm to several hundred μm, respectively. For example, in one or more embodiments, each of the plurality of light emitting elements LE may have a length in the first direction DR1, a length in the second direction DR2, and a length in the third direction DR3 of approximately 100 μm or less.

The light emitting element LE may include a conductive layer E1, a first semiconductor layer SEM1, an active layer MQW, a second semiconductor layer SEM2, a third semiconductor layer SEM3, a contact electrode CTE, and a protective layer INS.

The protective layer INS may be arranged on one surface (e.g., bottom surface) and a side surface of the conductive layer E1, a side surface of the first semiconductor layer SEM1, a side surface of the active layer MQW, and a side surface of the second semiconductor layer SEM2 and the third semiconductor layer SEM3. The protective layer INS may be a film for protecting the side surface of the light emitting element LE. The protective layer INS may be formed of an inorganic film, for example, silicon nitride (SiNₓ), silicon oxide (SiON), silicon oxide (SiOₓ), titanium oxide (TiOₓ), and/or aluminum oxide (AlOₓ).

The contact electrode CTE may be arranged on the protective layer INS. Each of the plurality of contact electrodes CTE may be arranged between the pixel electrodes PXE1, PXE2, and PXE3 and the protective layer INS.

The protective layer INS has one or more openings exposing the conductive layer E1. In one or more embodiments, the protective layer INS includes an (e.g., one) opening.

The contact electrode CTE may be connected to the exposed conductive layer E1 that is not covered by the protective layer INS.

The plurality of contact electrodes CTE may include at least one selected from among molybdenum (Mo), aluminum (Al), chromium (Cr), gold (Au), titanium (Ti), nickel (Ni), neodymium (Nd), and copper (Cu). For example, in one or more embodiments, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

A first protective layer INS1 may be arranged to cover all the pixel electrodes PXE1, PXE2, and PXE3 and the light emitting elements LE arranged on the pixel electrodes PXE1, PXE2, and PXE3. The first protective layer INS1 may cover all of the pixel electrodes PXE1, PXE2, and PXE3 on which the light emitting elements LE are not arranged.

A first organic layer 211 may be arranged on the first protective layer INS1 on which the light emitting elements LE are not arranged. For example, the first organic layer 211 may overlap at least a portion of the pixel electrodes PXE1, PXE2, and PXE3. The first organic layer 211 may be arranged to cover a portion of the side surfaces of the plurality of light emitting elements LE. For example, the first organic layer 211 may cover the side surfaces of the conductive layer E1, the first semiconductor layer SEM1, and the active layer MQW of the plurality of light emitting elements LE and may cover at least a portion of the side surface of the second semiconductor layer SEM2. The top surfaces of each of the plurality of light emitting elements LE may be exposed without being covered by the first organic layer 211.

In one or more embodiments, the first organic layer 211 may be arranged in an island pattern shape in each sub-pixel SPX1, SPX2, and SPX3. For example, the first organic layer 211 arranged in each sub-pixel SPX1, SPX2, and SPX3 may be arranged spaced and/or apart (e.g., spaced apart or separated) from the first organic layer 211 arranged in the adjacent sub-pixel SPX1, SPX2, and SPX3. For example, the first organic layer 211 may be arranged in an island shape around each sub-pixel SPX1, SPX2, and SPX3. For example, the first organic layer 211 forms isolated islands around each sub-pixel SPX1, SPX2, and SPX3, ensuring that there is no direct connection between the organic layers of adjacent sub-pixels.

A first reflective layer RF1 may be arranged on a side surface of the first organic layer 211. The first reflective layer RF1 surrounds the side surface of the first organic layer 211, thereby around (e.g., surrounding) the active layer MQW of the light emitting element LE. Therefore, the first reflective layer RF1 may minimize or reduce the loss of light emitted from the active layer MQW to the side and scattered.

A second protective layer INS2 may be arranged to cover an upper portion of the first organic layer 211 and the entire light emitting element LE that is not covered by the first organic layer 211. The second protective layer INS2 may not cover the side surface of the first organic layer 211. The second protective layer INS2 may be arranged on the other end (e.g., the end spaced from the first protective layer INS1) of the first reflective layer RF1.

A third protective layer INS3 may cover an upper portion of the second protective layer INS2 and be around (e.g., surround) a side surface of the first reflective layer RF1. Further, the third protective layer INS3 may be arranged on the first protective layer INS1 on which the first organic layer 211 is not arranged. The third protective layer INS3 may overlap the first partition wall BM1 described below in the third direction DR3.

The first reflective layer RF1 is arranged on the side of the first organic layer 211 but is protected by the protective layers INS1, INS 2, and INS3, so that there is no risk of contact with a common electrode CE or the pixel electrodes PXE1, PXE2, and PXE3.

The third protective layer INS3 and the second protective layer INS2 have openings that expose at least a portion of the upper portion of the light emitting element LE.

The common electrode CE may be arranged to overlap the first organic layer 211 on the top surface of each of the plurality of light emitting elements LE and the third protective layer INS3. The common electrode CE may be a common layer formed commonly on the first sub-pixel SPX1, the second sub-pixel SPX2, and the third sub-pixel SPX3.

The common electrode CE may be made of a transparent conductive material (TCO), such as indium tin oxide (ITO) and indium zinc oxide (IZO), which may transmit light.

The pixel electrodes PXE1, PXE2, and PXE3 may be referred to as an anode electrode or a first electrode, and the common electrode CE may be referred to as a cathode electrode or a second electrode.

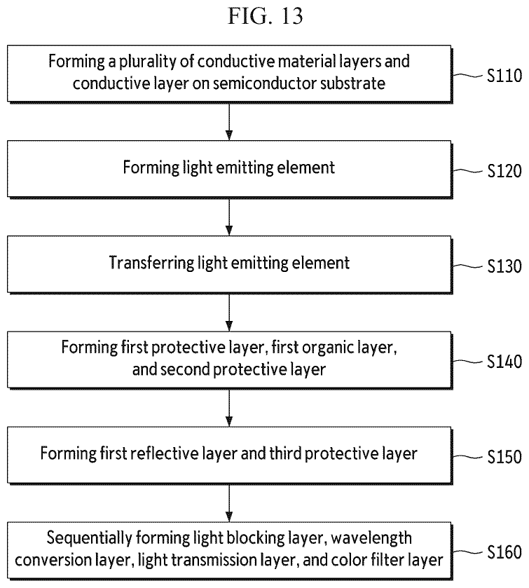

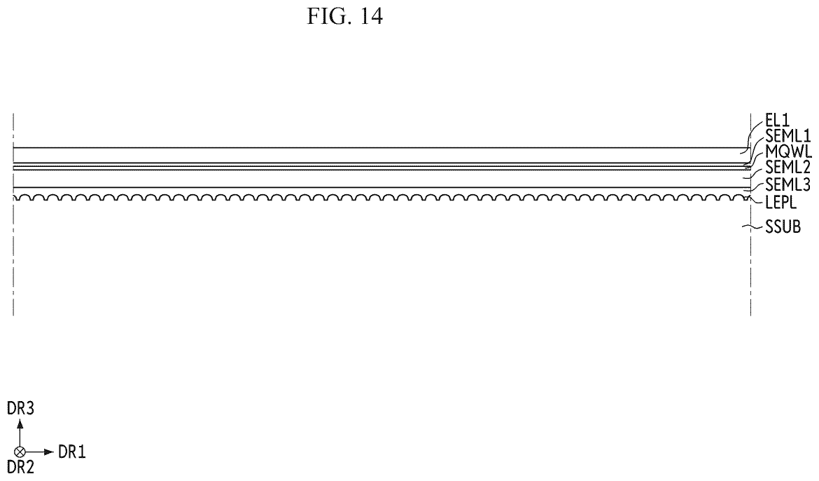

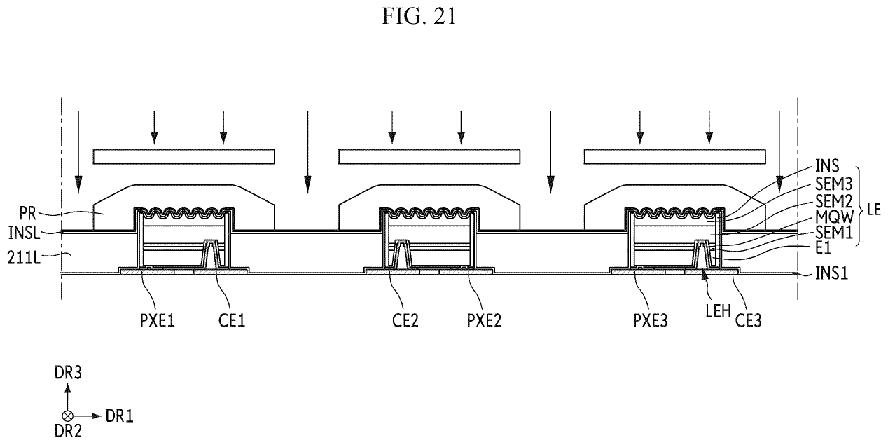

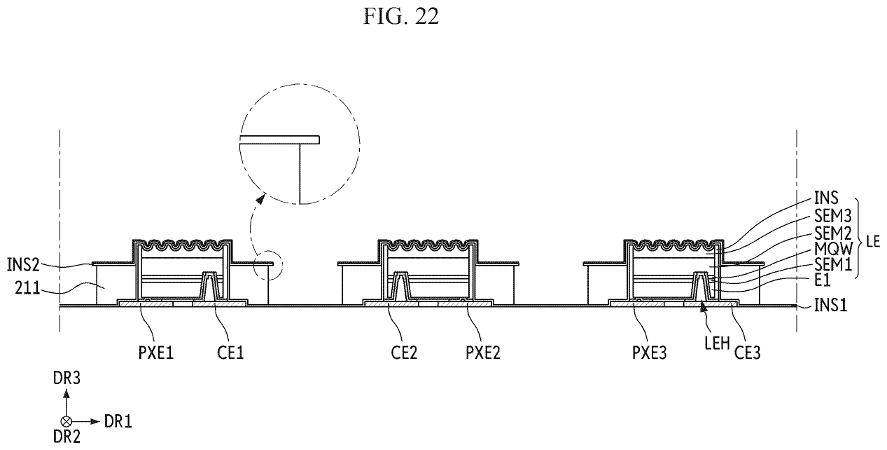

FIG. 13 is a flow chart illustrating a method of manufacturing a display device according to one or more embodiments of the present disclosure. FIGS. 14 to 26 are explanatory drawings to illustrate a method of manufacturing a display device according to one or more embodiments.

Hereinafter, a method for manufacturing a display device according to one or more embodiments will be described in more detail by connecting FIG. 13 with FIG. 14 to FIG. 26. The method for manufacturing a display device described with reference to FIG. 14 to FIG. 26 may be a display device including a light emitting element and/or a display panel described with reference to FIG. 5 to FIG. 7.

First, a plurality of semiconductor material layers SEML3, SEML2, MQWL, and SEML1 and a conductive layer EL1 are formed on a semiconductor substrate SSUB. (S110 in FIG. 13)

The semiconductor substrate SSUB may be a silicon wafer substrate or a sapphire substrate. A light extraction pattern layer LEPL is formed on a (e.g., one) surface of the semiconductor substrate SSUB. In one or more embodiments, the light extraction pattern layer LEPL may include convex patterns formed in a hemisphere or a semi-ellipse. The light extraction pattern layer LEPL may include convex patterns having a cross-sectional shape of a semicircle or a semi-ellipse. The light extraction pattern layer LEPL may be formed of a semiconductor material layer, an organic film, or an inorganic film.

Then, a third semiconductor material layer SEML3 is formed on the light extraction pattern layer LEPL. Due to the light extraction pattern layer LEPL, light extraction patterns (LEP in FIG. 7) may be formed on a (e.g., one) surface of the third semiconductor material layer SEML3. The third semiconductor material layer SEML3 may be a semiconductor material layer doped with a second conductive dopant, such as silicon (Si), germanium (Ge), or tin (Sn).

Then, a second semiconductor material layer SEML2 is formed on the third semiconductor material layer SEML3, an active material layer MQWL is formed on the second semiconductor material layer SEML2, and a first semiconductor material layer SEML1 is formed on the active material layer MQWL. The active material layer MQWL may include a same semiconductor material layer as the first semiconductor material layer SEML1, the second semiconductor material layer SEML2, and the third semiconductor material layer SEML3. For example, if (e.g., when) the first semiconductor material layer SEML1 and the second semiconductor material layer SEML2 include gallium nitride (GaN), the active material layer MQWL may also include gallium nitride GaN. For example, the active material layer MQWL may include at least one of gallium nitride (GaN), indium gallium nitride (InGaN), or aluminum gallium nitride (AlGaN). The first semiconductor material layer SEML1 may be a semiconductor material layer doped with a first conductive dopant, such as magnesium (Mg), zinc (Zn), calcium (Ca), strontium (Sr), barium (Ba), and/or the like.

The light extraction pattern layer LEPL, the third semiconductor material layer SEML3, the second semiconductor material layer SEML2, the active material layer MQWL, and the first semiconductor material layer SEML1 may each be formed on a semiconductor substrate SSUB through an epitaxial growth process. As an epitaxial growth process, an electron beam deposition method, a physical vapor deposition (PVD), a chemical vapor deposition (CVD), a plasma laser deposition (PLD), a dual-type (kind) thermal evaporation method, sputtering, a metal organic chemical vapor deposition (MOCVD), and/or the like may be used as a method of forming the light extraction pattern layer LEPL, the third semiconductor material layer SEML3, the second semiconductor material layer SEML2, the active material layer MQWL, and the first semiconductor material layer SEML1. In one or more embodiments, metal-organic chemical vapor deposition (MOCVD) may be used, but embodiments of the present disclosure are not limited thereto.

Then, a conductive material layer EL1 is formed on the third semiconductor material layer SEML3 and the first semiconductor material layer SEML1. The conductive material layer EL1 may be formed from any one (e.g., one or more) selected from among molybdenum (Mo), aluminum (Al), chromium (Cr), gold (Au), titanium (Ti), nickel (Ni), neodymium (Nd), and copper (Cu).

Second, light emitting elements LE are formed. (S120 in FIG. 13)

The third semiconductor material layer SEML3, the second semiconductor material layer SEML2, the active material layer MQWL, the first semiconductor material layer SEML1, and the conductive material layer EL1 are etched.

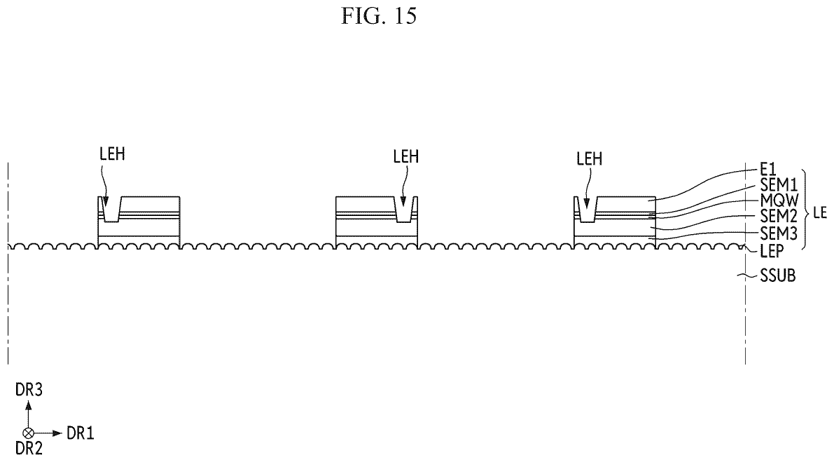

Referring to FIG. 15, after forming a mask pattern on the conductive material layer EL1, the third semiconductor material layer SEML3, the second semiconductor material layer SEML2, the active material layer MQWL, the first semiconductor material layer SEML1, and the conductive material layer EL1 are etched according to the mask pattern. The mask pattern may be removed after forming the light emitting elements LE.

The third semiconductor material layer SEML3, the second semiconductor material layer SEML2, the active material layer MQWL, the first semiconductor material layer SEML1, and the conductive material layer EL1 may be etched by a dry etching method, a wet etching method, a reactive ion etching method (RIE), a deep reactive ion etching method (DRIE), an inductively coupled plasma reactive ion etching method (ICP-RIE), and/or the like. In the embodiments of the dry etching method, anisotropic etching is possible, so it may be suitable for vertical etching. When the dry etching method is used, the etching gas may be chlorine (Cl₂) or oxygen (O₂) gas, but embodiments of the present disclosure are not limited thereto.

Then, a hole LEH is formed in each of the light emitting elements LE to penetrate the conductive layer E1, the first semiconductor layer SEM1, and the active layer MQW to expose the second semiconductor layer SEM2.

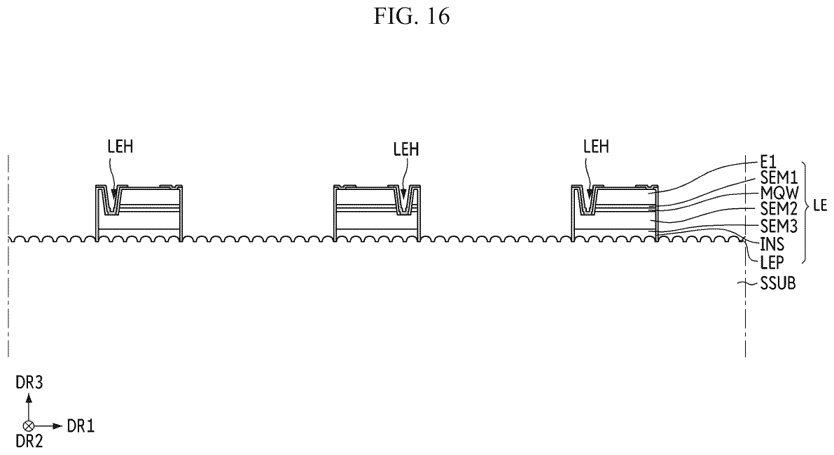

Thereafter, as shown in FIG. 16, a protective layer INS and cathode electrodes CTE1 and CTE2 are formed.

A protective material layer around (e.g., surrounding) the light emitting elements LE is formed, and a mask pattern is formed on the protective material layer.

The protective material layer may be completely deposited on one surface of the semiconductor substrate SSUB. The protective material layer may be formed to cover one surface and side surfaces of the light emitting elements LE. The protective material layer may be formed on one surface of the semiconductor substrate SSUB exposed between the light emitting elements LE.

The mask pattern may be formed to expose a portion of the hole LEH of each of the light emitting elements LE. For example, the mask pattern may be formed so as not to cover the protective material layer arranged on a bottom surface of the hole LEH of each of the light emitting elements LE. Further, the mask pattern may be arranged to expose a portion of the protective material layer arranged on one surface of each of the light emitting elements LE.

The protective material layer not covered by the mask pattern is etched. Then, the mask pattern may be removed by an ashing process.

Thereafter, a contact electrode layer is completely deposited on one surface of the semiconductor substrate SSUB and a portion of the contact electrode layer is etched using the mask pattern to form contact electrodes.

Then, the mask pattern may be removed by an ashing process.

Third, the light emitting elements LE are transferred onto a circuit board. (S130 in FIG. 13)

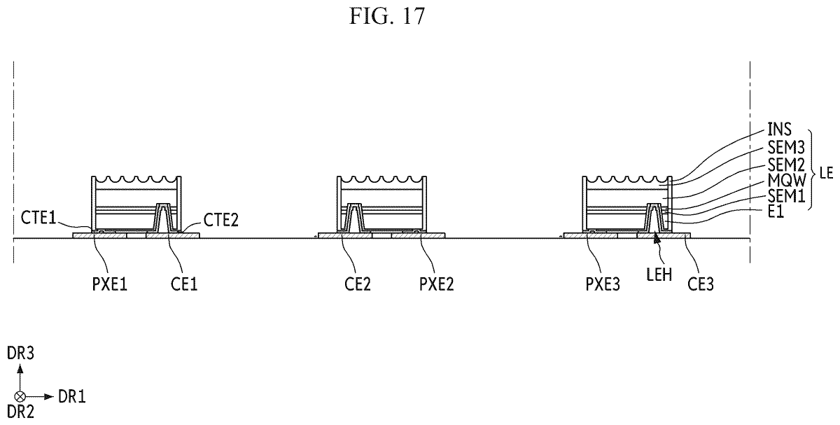

As shown in FIG. 17, the light emitting elements LE may be transferred onto the pixel electrode PXE1 and the common electrode CE1. It is exemplified that the first contact electrode CTE1 of each light emitting element LE is arranged on the pixel electrode PXE1, PXE2, and PXE3, and the second contact electrode CTE2 is arranged on the common electrode CE1, CE2, and CE3.

Fourth, a first protective layer INS1, a first organic layer 211, and a second protective layer INS2 are formed. (S140 in FIG. 13)

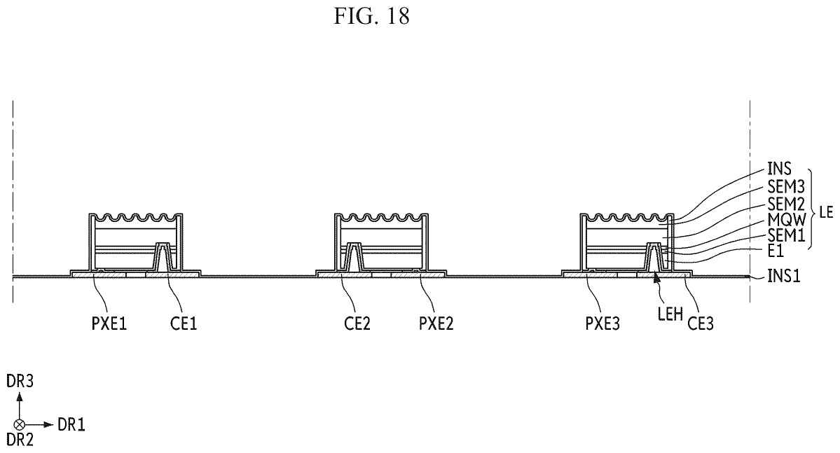

As shown in FIG. 18, a protective material layer covering the light emitting elements LE is formed.

The protective material layer may be deposited on the entire surface of the circuit board to cover a portion of the pixel electrodes PXE1, PXE2, and PXE3 and the common electrodes CE1, CE2, and CE3.

The protective material layer may be formed on the surface of the circuit board exposed between the pixel electrodes PXE1, PXE2, and PXE3 and the common electrodes CE1, CE2, and CE3.

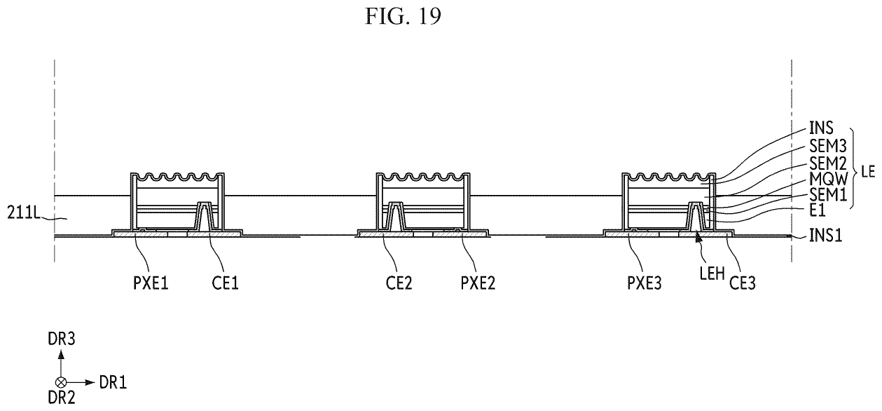

Then, as shown in FIG. 19, an organic material layer 211L is formed to fix the light emitting elements LE and flatten the steps caused by the light emitting elements LE. The organic material layer 211L may fill all the space between the light emitting elements LE, but a height of the organic material layer 211L may be formed lower than a height of the light emitting elements LE to expose an upper portion of the light emitting elements LE.

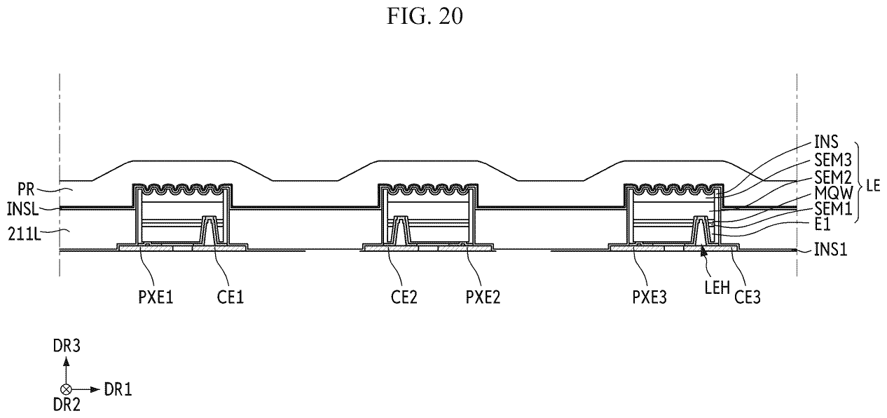

Thereafter, a protective material layer INSL is deposited on the entire surface of the circuit board to cover the light emitting elements LE and the organic material layer 211L, and a hard mask is formed. For example, as shown in FIGS. 20 to 22, a photoresist PR is applied on the entire surface to cover the protective material layer INSL, and the photoresist PR is patterned using a mask pattern. The protective material layer INSL and the organic material layer 211L are patterned using the photoresist pattern, and dry etched to form a second protective layer INS2 and a first organic layer 211. By patterning, each sub-pixel of the first organic layer 211 may be formed in an island pattern shape. The etching rate of the first organic layer 211 is higher than that of the second protective layer INS2, so that an (e.g., one) end of the second protective layer INS2 may protrude outside the first organic layer 211 to form a tip.

The first protective layer INS1 may protect the pixel electrodes PXE1, PXE2, and PXE3 and the common electrodes CE1, CE2, and CE3 during dry etching.

Fifth, a first reflective layer RF1 and a third protective layer INS3 are formed. (S150 in FIG. 13)

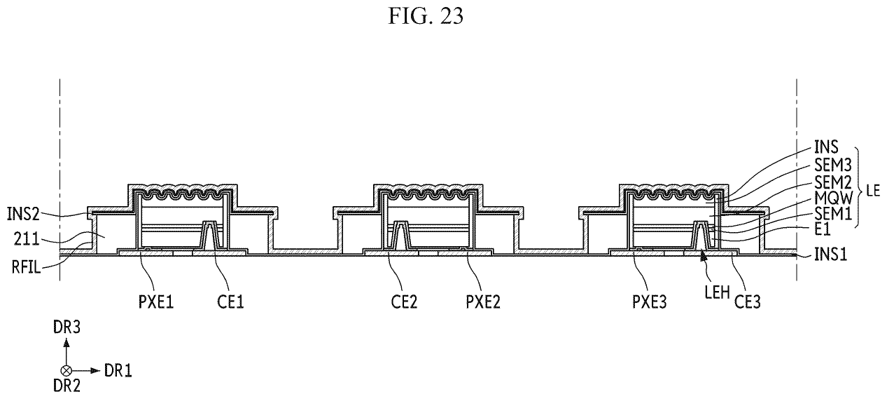

As shown in FIG. 23, a reflective material layer RFIL is deposited on the entire surface of the circuit board to cover the light emitting element LE and the first organic layer 211.

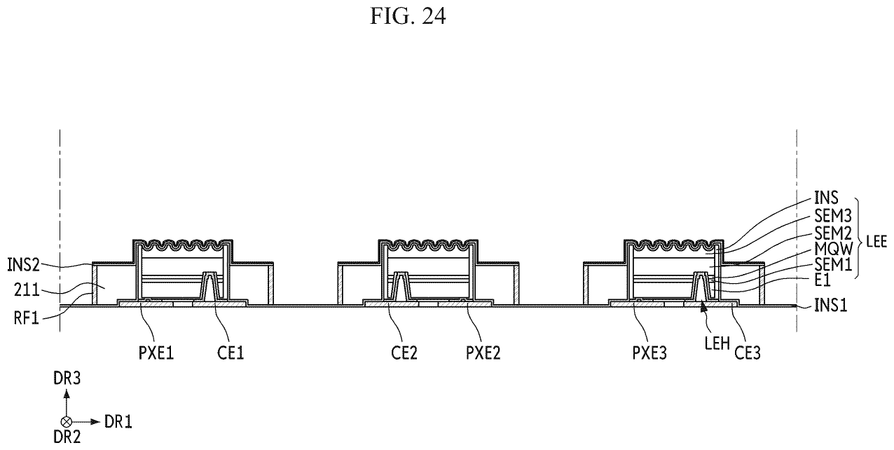

Then, as shown in FIG. 24, dry etching is performed so that only the reflective material layer arranged on the side of the first organic layer 211 remains, thereby forming the first reflective layer RF1. Anisotropic etching may be possible through dry etching. Furthermore, the tip protruding outwardly of the second protective layer INS2 prevents the etching of the reflective material layer at the bottom of the tip, so that the first reflective layer RF1 may be formed on the side of the first organic layer 211. The reflective material on the upper portion of the other light emitting element LE, the upper portion of the first organic layer 211, and the upper portion of the first protective layer INS1 between the first organic layers 211 may be removed.

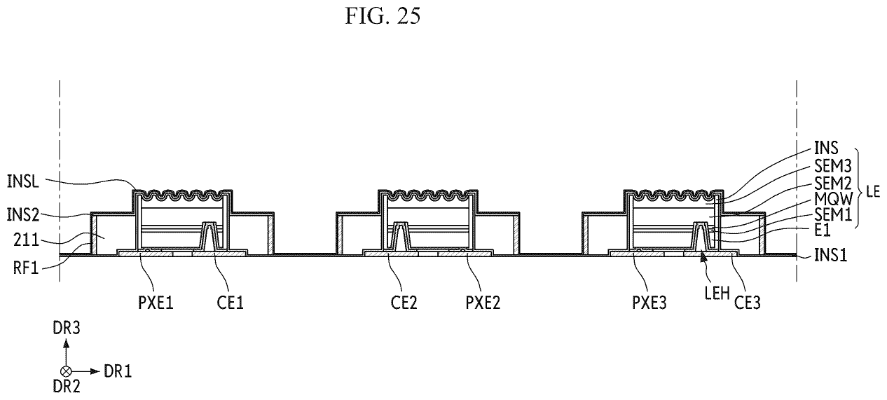

As shown in FIG. 25, a protective material layer INSL is completely deposited on the circuit board on which the first reflective layer RF1 is formed to form a third protective layer INS3.

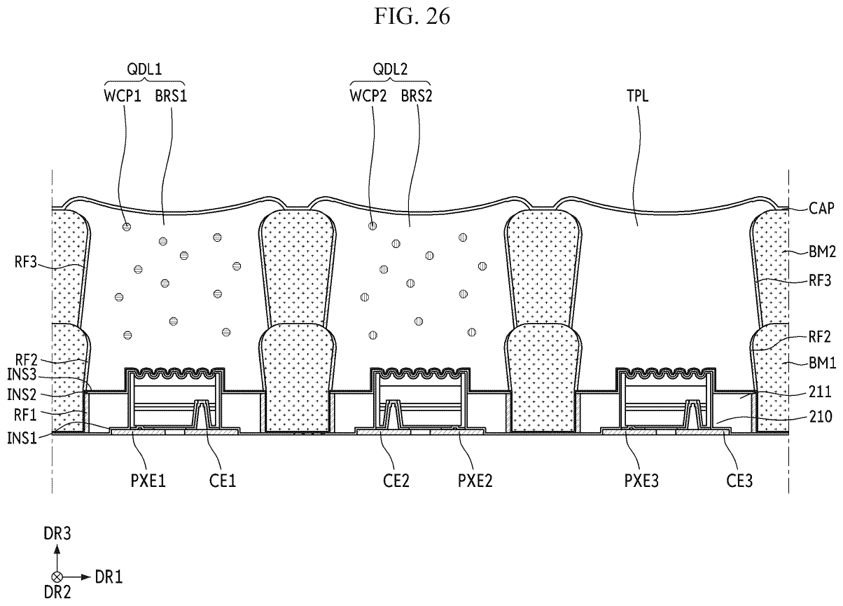

Sixth, as shown in FIG. 26, a light blocking layer, a wavelength conversion layer, a light transmission layer, and a color filter layer are sequentially formed. (S160 in FIG. 13)

A first capping layer CPL1 is formed on the third organic film 213 and the light emitting elements LE, and a first partition wall BM1 and a second partition wall BM2 are formed on the first capping layer CPL1 so as not to overlap with the light emitting elements LE in the third direction DR. Then, a second capping layer CPL2 covering the first partition wall BM1, the second partition wall BM2, and the first capping layer CPL1 is formed. Then, a reflective layer RF2 covering the second capping layer CPL2 arranged on the first partition wall BM1 and the second partition wall BM2 is formed.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a capping layer CAP (see FIG. 6) is formed covering the first light conversion layers QDL1, the second light conversion layers QDL2, and the light transmission layers TPL. Then, a fourth organic film 213 is formed on the capping layer CAP.

Then, a first color filter CF1 is formed on the fourth organic film 213 overlapping the first light conversion layers QDL1 in the third direction DR3, a second color filter CF2 is formed overlapping the second light conversion layers QDL2 in the third direction DR3, and a third color filter CF3 is formed overlapping the light transmission layers TPL in the third direction DR3. The first color filter CF1, the second color filter CF2, and the third color filter CF3 may all be formed in the region overlapping the first partition wall BM1 and the second partition wall BM2 in the third direction DR3.

Then, a fifth organic film 214 is formed on the first color filter CF1, the second color filter CF2, and the third color filter CF3.

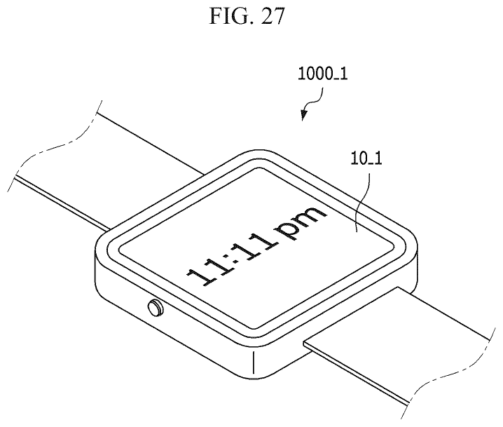

FIG. 27 is an example view of a smart watch including a display device according to one or more embodiments of the present disclosure.

Referring to FIG. 27, a display device 10_1 according to one or more embodiments may be applied to a smart watch 1000_1, which is one of smart devices.

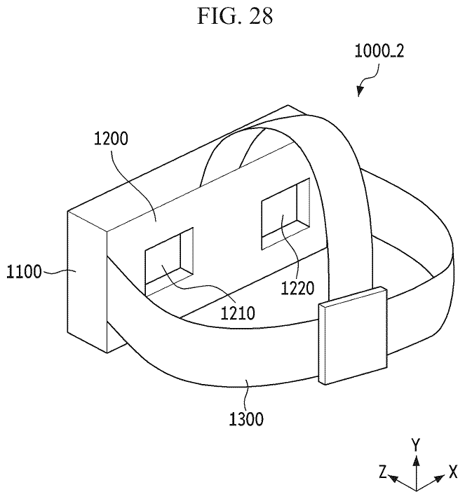

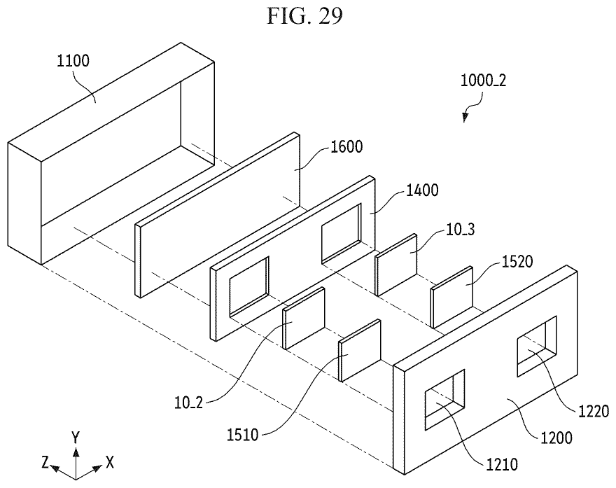

FIG. 28 and FIG. 29 are example views of a virtual reality (VR) device including a display device according to one or more embodiments of the present disclosure.

Referring to FIG. 28 and FIG. 29, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to a user's right eye. Each of the first display device 10_2 and the second display device 10_3 is substantially the same as the display device 10 described with reference to FIG. 1 and FIG. 2. Therefore, descriptions of the first display device 10_2 and the second display device 10_3 will not be provided for conciseness.

The first optical member 1510 may be arranged between the first display device 10_2 and the first eyepiece 1210. The second optical member 1520 may be arranged between the second display device 10_3 and the second eyepiece 1220. Each of the first optical member 1510 and the second optical member 1520 may include at least one convex lens.

The middle frame 1400 may be arranged between the first display device 10_2 and the control circuit board 1600 and may be arranged between the second display device 10_3 and the control circuit board 1600. The middle frame 1400 supports and fixes the first display device 10_2, the second display device 10_3, and the control circuit board 1600.

The control circuit board 1600 may be arranged between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

In one or more embodiments, the control circuit board 1600 may be to transmit the digital video data DATA corresponding to a left image improved or optimized for the user's left eye to the first display device 10_2 and transmit the digital video data DATA corresponding to a right image improved or optimized for the user's right eye to the second display device 10_3. In one or more embodiments, the control circuit board 1600 may be to transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 at which a user's left eye looks and the second eyepiece 1220 at which the user's right eye looks. Although the first eyepiece 1210 and the second eyepiece 1220 are arranged separately in FIG. 28 and FIG. 29, embodiments of the present specification are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

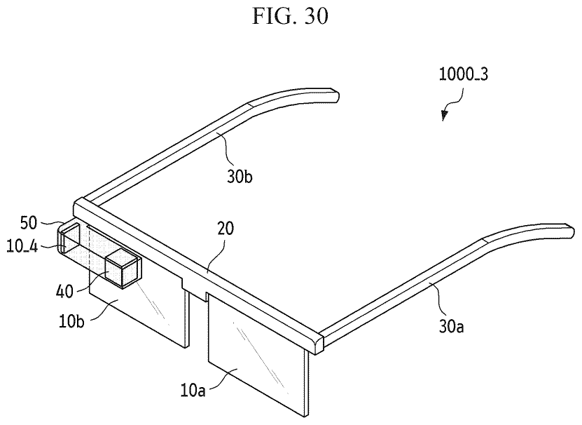

The head mounted band 1300 fixes the display device housing 1100 to a user's head so that the first eyepiece 1210 and the second eyepiece 1220 of the housing cover 1200 are kept placed on the user's left and right eyes, respectively. In one or more embodiments, when the display device housing 1200 is implemented to be lightweight and small, the head mounted display device 1000_2 may include an eyeglass frame as illustrated in FIG. 30 instead of the head mounted band 1300.

In one or more embodiments, the head mounted display device 1000_2 may further include a battery for supplying power, an external memory slot for accommodating an external memory, and an external connection port and a wireless communication module for receiving an image source. The external connection port may be at least one of a universe serial bus (USB) terminal, a display port, or a high-definition multimedia interface (HDMI) terminal, and the wireless communication module may be at least one of a 5G communication module, a 4G communication module, a Wi-Fi module, or a Bluetooth module.

FIG. 30 is an example view of a VR device including a display device according to one or more embodiments of the present disclosure. FIG. 30 illustrates a VR device 1000_3 to which a display device 10_4 according to one or more embodiments has been applied.

Referring to FIG. 30, the VR device 1000_3 according to one or more embodiments may be a device in the form of glasses. The VR device 1000_3 according to one or more embodiments may include the display device 10_4, a left lens 10a, a right lens 10b, a support frame 20, eyeglass frame legs 30a and 30b, a reflective member 40, and a display device housing 50.

In FIG. 30, an embodiment in which the VR device 1000_3 is a glasses-type (kind) display device including the eyeglass frame legs 30a and 30b is illustrated as an example. For example, the VR device 1000_3 according to one or more embodiments is not limited to the one illustrated in FIG. 30 and can be applied in one or more suitable forms to various suitable other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is arranged at a right end of the support frame 20 in FIG. 30, embodiments of the present specification are not limited thereto. For example, in one or more embodiments, the display device housing 50 may also be arranged at a left end of the support frame 20. In these embodiments, an image displayed on the display device 10_4 may be reflected by the reflective member 40 and provided to the user's left eye through the left lens 10a. Accordingly, the user may view a VR image displayed on the display device 10_4 through the left eye. In one or more embodiments, the display device housing 50 may be arranged at both (e.g., simultaneously) the right end and the left end of the support frame 20. In these embodiments, the user may view a VR image displayed on the display device 10_4 through both (e.g., simultaneously) the left eye and the right eye.

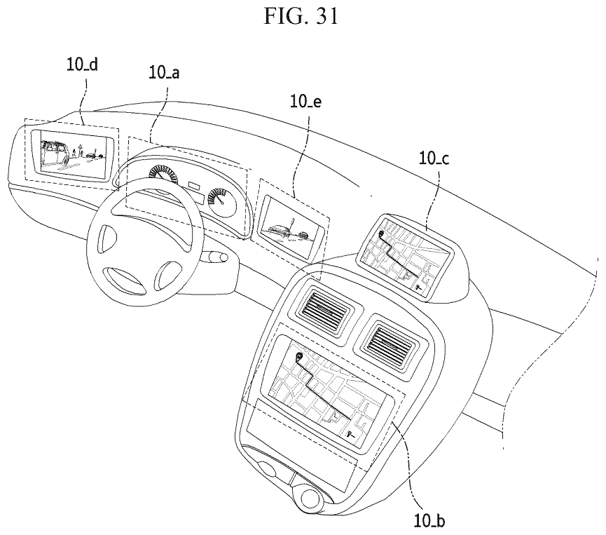

FIG. 31 is an example view illustrating a vehicle instrument cluster and center fascia including display devices according to one or more embodiments of the present disclosure. FIG. 31 illustrates a vehicle to which display devices 10_a through 10_e according to one or more embodiments have been applied.

Referring to FIG. 31, the display devices 10_a through 10_c according to one or more embodiments may be applied to an instrument cluster of the vehicle, a center fascia of the vehicle, or a center information display (CID) arranged on a dashboard of the vehicle. In addition, the display devices 10_d and 10_e according to one or more embodiments may be applied to room mirror displays that replace side mirrors of the vehicle.

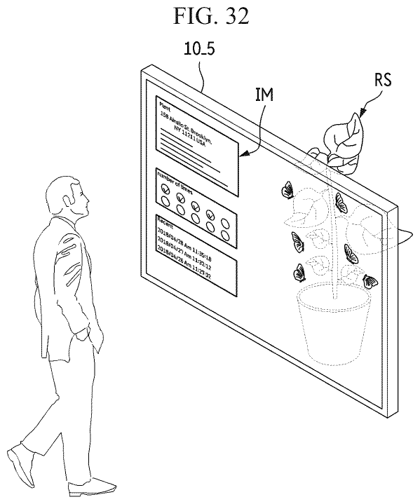

FIG. 32 is an example view of a transparent display device including a display device according to one or more embodiments of the present disclosure.

Referring to FIG. 32, a display device 10_5 according to one or more embodiments may be applied to a transparent display device. The transparent display device may be to transmit light while displaying an image IM. Therefore, a user located in front of the transparent display device may not only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,”“utilizing,”and “utilized,”respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

The light emitting element, the display module, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with one other, partially or entirely, and may be technically interlocked and operated in various suitable ways, and each embodiment may be implemented independently of one other or in conjunction with one other in any suitable manner unless otherwise stated or implied.

In concluding the detailed description, those skilled in the art will appreciate that many variations and modifications may be made to one or more embodiments without substantially departing from the principles of the disclosure. Therefore, the disclosed embodiments of the disclosure are used in a generic and descriptive sense only and not for purposes of limitation. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
a pixel electrode layer on the substrate;
a light emitting element on the pixel electrode layer and comprising a contact electrode;
an organic layer in an island pattern shape covering a portion of a side surface of the light emitting element and a portion of the pixel electrode layer exposed by the light emitting element;
a first reflective layer on a side surface of the organic layer; and
a protective layer protecting the light emitting element, the organic layer, and the first reflective layer.

2. The display device of claim 1, wherein the protective layer comprises,
a first protective layer covering a top surface and side surfaces of the light emitting element and the pixel electrode layer on which the light emitting element is not arranged;
a second protective layer on a top surface of the organic layer and the top surface and side surfaces of the light emitting element; and
a third protective layer on the second protective layer, and on the light emitting element, the organic layer, and the substrate on which the organic layer is not arranged.

3. The display device of claim 2, wherein the second protective layer has a tip protruding outward from the top surface of the organic layer, and
wherein the first reflective layer is arranged below the tip.

4. The display device of claim 1, wherein the organic layer has a cross-section of one selected from among a dome shape, a rectangle shape, and a trapezoid shape.

5. The display device of claim 1, wherein the organic layer has a shape that gradually narrows as it goes upward in a thickness direction of the display device.

6. The display device of claim 5, wherein the side surface of the organic layer and the first reflective layer each have an inclination angle in a range of about 55° to about 85°.

7. The display device of claim 1, wherein the light emitting element comprises:
a conductive layer on a bottom surface of a first semiconductor layer, the first semiconductor layer on the conductive layer and comprising a semiconductor material layer doped with a first conductive dopant;
an active layer on the first semiconductor layer; and
a second semiconductor layer on the active layer and comprising a semiconductor material layer doped with a second conductive dopant, and
wherein the organic layer surrounds a side surface of the conductive layer, the first semiconductor layer, and the active layer.

8. The display device of claim 7, wherein the light emitting element further comprises a third semiconductor layer, which is an undoped semiconductor layer, on the second semiconductor layer.

9. The display device of claim 8, wherein the light emitting element further comprises a light extraction pattern having a concave pattern on an upper portion of the light emitting element.

10. The display device of claim 7, wherein the contact electrode comprises:
a first contact electrode on a protective film and connected to the conductive layer exposed without being covered by the protective film; and
a second contact electrode on the protective film and in a hole penetrating the conductive layer and a portion of a semiconductor stack, the semiconductor stack comprising the first semiconductor layer, the active layer, and the second semiconductor layer,
wherein the pixel electrode layer comprises a pixel electrode and a common electrode that are spaced from each other, and
wherein the first contact electrode is connected to the pixel electrode, and the second contact electrode is connected to the common electrode.

11. The display device of claim 7, wherein the pixel electrode layer comprises a pixel electrode, and
wherein the contact electrode is on the pixel electrode and is connected to the conductive layer that is exposed and not covered by a protective film.

12. The display device of claim 11, further comprising a common electrode on the light emitting element and the organic layer,
wherein the protective layer comprises an opening that exposes at least a portion of an upper portion of the light emitting element, and the upper portion of the light emitting element is connected to the common electrode through the opening.

13. The display device of claim 1, further comprising:
a partition wall arranged to surround the light emitting element; and
a reflective layer on a side surface of the partition wall and a bottom of a space formed by the partition wall.

14. The display device of claim 13, further comprising a wavelength conversion layer arranged in the space formed by the partition wall.

15. A method, comprising:
forming a light emitting element comprising a plurality of semiconductor layers, a conductive layer, a protective layer, and a contact electrode;
transferring the light emitting element onto a circuit board;
forming a first protective layer by applying a first layer to a side of the light emitting element and the circuit board on which the light emitting element is not arranged;
forming an organic material layer covering the side of the light emitting element, forming a protective material layer to cover the light emitting element and the organic material layer, and patterning the protective material layer and the organic material layer to form an organic layer and a second protective layer;
completely depositing a reflective material layer to cover the light emitting element and the organic layer, and dry etching to form a first reflective layer to be arranged on a side of the organic layer; and
forming a third protective layer around the organic layer and the light emitting elements,
wherein the method is a method for manufacturing a display device.

16. The method of claim 15, wherein, in the forming of the organic layer and the second protective layer,
the organic layer is formed in an island pattern by dry etching utilizing a hard mask on the protective material layer, and the second protective layer having a tip protruding outward from a top surface of the organic layer is formed.

17. The method of claim 16, wherein the first reflective layer is located below the protruding tip.

18. The method of claim 15, wherein the forming of the light emitting element comprises:
forming a second semiconductor material layer, an active material layer, a first semiconductor material layer, and a conductive material layer on a semiconductor substrate;
etching the second semiconductor material layer, the active material layer, the first semiconductor material layer, and the conductive material layer to form light emitting elements each comprising a second semiconductor layer, an active layer, a first semiconductor layer, and a conductive layer;
forming a hole penetrating the conductive layer, the first semiconductor layer, and the active layer in each of the light emitting elements;
forming a protective material layer around each of the light emitting elements and patterning the protective material layer to form a protective film; and
forming a mask pattern on the protective film and forming a contact electrode.

19. The method of claim 15, further comprising:
forming a partition wall defining a light emitting area;
forming a wavelength conversion layer in a space formed by the partition wall; and
forming an overcoat layer and a color filter layer sequentially arranged on the partition wall and the wavelength conversion layer.

20. An electronic device, comprising a display device,
wherein the display device comprises:
a substrate;
a pixel electrode layer on the substrate;
a light emitting element on the pixel electrode layer and comprising a contact electrode;
an organic layer in an island pattern shape covering a portion of a side surface of the light emitting element and a portion of the pixel electrode layer exposed by the light emitting element;
a first reflective layer on a side surface of the organic layer; and
a protective layer protecting the light emitting element, the organic layer, and the first reflective layer.
